(19) United States
(12) Patent Application Publication
(10) Pub. No.: US 2025/0107423 A1
(43) Pub. Date: Mar. 27, 2025

(54) REDOX DOPING METHOD FOR HIGH-PERFORMANCE SN PEROVSKITE SOLAR CELLS

(71) Applicants: The Hong Kong University of Science and Technology, Hong Kong (CN); Jilin University, Changchun City (CN)

(72) Inventors: Yuanyuan ZHOU, Hong Kong (CN); Ning WANG, Changchun City (CN)

(21) Appl. No.: 18/891,016

(22) Filed: Sep. 20, 2024

Related U.S. Application Data
(60) Provisional application No. 63/585,224, filed on Sep. 26, 2023.

(51) Int. Cl. H10K 71/30; C07F 19/00; H10K 30/30; H10K 30/40; H10K 30/50; H10K 71/15; H10K 85/50

(52) U.S. Cl. CPC H10K 71/30; C07F 19/005; H10K 30/30; H10K 30/40; H10K 30/50; H10K 71/15; H10K 85/50

(57) ABSTRACT

Europium doped tin perovskites useful in the fabrication of optoelectronic devices exhibiting improved stability and high-power conversion efficiencies and perovskite precursor solutions used to prepare the europium doped tin perovskite, wherein the europium doped tin perovskite can be represented by Formula 1:

(A⁺)(Sn²⁺)(X⁻)₃·m[(Eu²⁺)(Y⁻)₂] 1
wherein m is 0.001-0.05;
X⁻ for each instance is independently F⁻, Cl⁻, Br⁻, or I⁻;
Y⁻ for each instance is independently F⁻, Cl⁻, Br⁻, or I⁻; and
A⁺ is Cs⁺, Rb⁺, CH₃NH₃⁺, CH₃CH₂NH₃⁺, H(C═NH₂)NH₂⁺, Me(C═NH₂)NH₂⁺, or a mixture thereof.

### CROSS-REFERENCE TO RELATED APPLICATIONS

The present application claims priority from U.S. Provisional Patent Application No. 63/585,224, filed on Sep. 26, 2023, which is hereby incorporated by reference in its entirety.

### STATEMENT REGARDING PRIOR DISCLOSURES BY THE INVENTORS OR JOINT INVENTORS UNDER 37 CFR 1.77 (b) (6)

Part of the present invention was disclosed in a paper published in Xue Ma, et al., Europium redox doping to suppress Sn—I defect pairs in Sn perovskite photovoltaics, Device, volume 2, Issue 6, 100294, available online 28 Feb. 2024. This paper is a grace period inventor-originated disclosure disclosed within one year before the filing date of this application and falls within the exceptions defined under 35 USC § 102(b)(1). This paper is hereby incorporated by reference in its entirety.

### TECHNICAL FIELD

This disclosure relates to europium doped tin perovskites and optoelectronic devices comprising the same, and perovskite precursor solutions useful in the preparation of the europium doped tin perovskites.

### BACKGROUND

Metal halide perovskite solar cells (PSCs) are considered a disruptive photovoltaic technology owing to the rapid rise of their power conversion efficiencies (PCEs). However, high-performance PSCs are often based on metal halide perovskites with the lead (Pb) as the core metal cation, while Pb is known detrimentally to the environment and human beings. Given restrictions for using Pb in commercial optoelectronic devices, application in PSCs is limited. In order to mitigate the Pb-toxicity issue of PSCs while preserving the desirable device performance, one important method is to replace Pb cations with less toxic metal cations, in particular tin (Sn) which exhibits a similar electron configuration. Sn-PSCs have demonstrated high potential with a maximum PCE of 14.81% reported. In addition, Sn perovskites with lower bandgaps are more ideal for sunlight absorption as compared to Pb perovskites. Nevertheless, Sn cations in perovskites can readily undergo oxidation from Sn²⁺ to Sn⁴⁺, which is coupled with the formation of Sn vacancies (V_{Sn}) to maintain the local charge neutrality among the crystalline lattice. The uncontrolled increase of V_{Sn} in perovskites can severely reduce the structural stability and bring about negative effects on the optoelectronic properties. Addressing the Sn oxidation issue has thus been of significance for pursuing highly stable and efficient Sn PSCs.

Efforts have primarily focused on incorporating various functional molecules into Sn perovskite processing, leading to increased oxidation tolerance of the resultant perovskite films via surface and interface passivation. However, obstacles of charge extraction/transfer are generally encountered at the perovskite layer and its interfaces due to the insulative properties of the passivation molecules. Alternatively, metal ion doping has been applied to improve the performance and stability of Sn PSC devices. The general rational of metal ion doping is to introduce a suitable amount of isovalent or aliovalent metal cations into the perovskite lattice to modify the electronic and optical properties. The interstitial doping of alkali metal cations such as lithium (Li⁺), sodium (Na⁺), potassium (K⁺), or rubidium (Rb⁺) has been widely employed to suppress ion migration in perovskite materials, thereby enhancing the performance and stability of perovskite optoelectronic devices. However, these doping processes can distort the perovskite lattice, leading to lattice microstrain, which can compromise the stability of the crystal. Therefore, the choice of an appropriate ion is crucial to mitigate these side effects while maximizing the suppression of ion migration, thereby promoting the performance and operational stability of PSCs.

There thus exists a need for improved Sn PSCs that address or overcome at least some of the challenges described above.

### SUMMARY

In this work, we applied an optimized amount of europium diiodide (EuI₂) to serve as the metal ion dopants, which can greatly suppress the concentration of Sn⁴⁺ and under-coordinated I⁻ in Sn perovskites. We investigated the mechanisms underlying this effective approach. We found the precursor solution of Sn perovskites in dimethyl sulfoxide (DMSO) solvent is acidic. The redox reactions between Eu²⁺ and Sn⁴⁺, iodine (I⁰) are more energetically favored in such acidic mediator. These reactions can reduce the concentration of Sn—I defect pairs in Sn perovskites. By combining density functional theory (DFT) calculations and experimental approaches, the Eu²⁺ cation was confirmed to migrate into the perovskite lattice, which enables not only the change of the local structure in Sn—I frameworks to create a reduced energy barrier for the redox process, but also the stabilization of organic cation components to enhance the thermal stability of the Sn perovskite lattice. As a result, Sn PSCs deliver a high PCE up to 13.66%, along with an open-circuit voltage (V_{OC}) of 0.72 V, a short-circuit current density (J_{SC}) of 24.21 mA/cm² and a fill factor (FF) of 78.34%.

In a first aspect, provided herein is a perovskite comprising Sn²⁺ and Eu²⁺.

In certain embodiments, the perovskite further comprises one or more A⁺ selected from the group consisting of Cs⁺, Rb⁺, CH₃NH₃⁺, CH₃CH₂NH₃⁺, NH₂CH═NH₂⁺, and NH₂C(Me)=NH₂⁺.

In certain embodiments, the perovskite further comprises NH₂CH═NH₂⁺.

In certain embodiments, Eu²⁺ and Sn²⁺ are present in the perovskite at a molar ratio of 0.01:99.99 to 5:95, respectively.

In certain embodiments, Eu²⁺ and Sn²⁺ are present in the perovskite at a molar ratio of 0.5:99.5 to 2:98, respectively.

In certain embodiments, the perovskite further comprises NH₂CH═NH₂⁺, and Eu²⁺ and Sn²⁺ are present in the perovskite at molar ratio of 0.5:99.5 to 2:98, respectively.

In certain embodiments, the perovskite has Formula 1:

(A⁺)(Sn²⁺)(X⁻)₃·m[(Eu²⁺)(Y⁻)₂] 1
wherein m is 0.001-0.05;
X⁻ for each instance is independently F⁻, Cl⁻, Br⁻, or I⁻;
Y⁻ for each instance is independently F⁻, Cl⁻, Br⁻, or I⁻; and
A⁺ is Cs⁺, Rb⁺, CH₃NH₃⁺, CH₃CH₂NH₃⁺, H(C═NH₂)NH₂⁺, Me(C═NH₂)NH₂⁺, or a mixture thereof.

In certain embodiments, A⁺ is H(C═NH₂)NH₂⁺.

In certain embodiments, m is 0.005-0.02.

In certain embodiments, A⁺ is H(C═NH₂)NH₂⁺ and m is about 0.01.

In certain embodiments, each of X⁻ and Y⁻ is I.

In certain embodiments, the perovskite has Formula 2:

(H(C═NH₂)NH₂⁺)(Sn²⁺)(I⁻)₃·m[(Eu²⁺)(I⁻)₂] 2

wherein m is about 0.010101.

In a second aspect, provided herein is a perovskite precursor solution comprising one or more tin salts, EuY₂, AZ, optionally tin powder, and a solvent, wherein the one or more tin salts is represented by the formula SnX₂, A is Cs⁺, Rb⁺, CH₃NH₃⁺, CH₃CH₂NH₃⁺, H(C═NH₂)NH₂⁺, Me(C═NH₂)NH₂⁺, or a mixture thereof, X for each instance is independently F⁻, Cl⁻, Br⁻, I⁻, or a mixture thereof, Y for each instance is independently F⁻, Cl⁻, Br⁻, I⁻, or a mixture thereof, Z is F⁻, Cl⁻, Br⁻, or I⁻, and the solvent comprises dimethyl formamide (DMF), dimethyl sulfoxide (DMSO), or a mixture thereof.

In certain embodiments, the one or more tin salts comprises SnF₂, SnCl₂, and SnI₂.

In certain embodiments, AZ is H(C═NH₂)NH₂I.

In certain embodiments, Y is I⁻.

In certain embodiments, the perovskite precursor solution further comprises ethanediamine dihydroiodide.

In certain embodiments, the perovskite precursor solution comprises tin powder, SnF₂, SnCl₂, SnI₂, EuI₂, H(C═NH₂)NH₂I, and DMSO.

In a third aspect, provided herein is an electronic device comprising:
a substrate layer;
a transparent conductive layer disposed on a surface of the substrate layer,
a hole-transport layer disposed on the surface of the transparent conductive layer;
a perovskite layer comprising the perovskite described herein disposed on a surface of the hole-transport layer;
an electron-transport layer disposed on the surface of the perovskite functional layer; and
a metal electrode disposed on the surface of the electron-transport layer.

In certain embodiments, the electronic device has a power conversion efficiency (PCE) of 12-13.66%.

In certain embodiments, the perovskite has Formula 2:

(H(C═NH₂)NH₂⁺)(Sn²⁺)(I⁻)₃·m[(Eu²⁺)(I⁻)₂] 2

wherein m is about 0.010101 and the electronic device is more stable than an electronic device comprising a perovskite of Formula 3:

(H(C═NH₂)NH₂⁺)(Sn²⁺)(I⁻)₃ 3

### BRIEF DESCRIPTION OF THE DRAWINGS

The present invention is illustrated by the accompanying drawings of various embodiments and the detailed description given below. The drawings should not be taken to limit the invention to the specific embodiments but are for explanation and understanding. The detailed description and drawings are merely illustrative of the invention rather than limiting, the scope of the invention being defined by the appended claims and equivalents thereof. The drawings are not to scale. The foregoing aspects and other attendant advantages of the present invention will become more readily appreciated by the detailed description taken in conjunction with the accompanying drawings.

FIG. 1. Crystal structure and grain distribution for perovskite films (A-C) Depth-dependent grazing incident X-ray diffraction (GIXRD) patterns of control, Sn⁰-incorporated and Sn⁰—Eu²⁺ incorporated FASnI₃ perovskite films. (D-F) SEM images of control, Sn⁰-incorporated, and Sn⁰—Eu²⁺ incorporated FASnI₃ perovskite films deposited on PEDOT:PSS-coated ITO substrates. The scale bar represents 1 μm. (G-I) The grain-size-distribution histograms from corresponding SEM images for the control, Sn⁰-incorporated and Sn⁰—Eu²⁺ incorporated samples, respectively.

FIG. 2. Characterization and calculations of Eu²⁺-incorporated perovskite films: crystal structure, electron localization, charge transfer, and redox properties (A) Schematic illustration for the typical FASnI₃ crystal structure and the calculated formation energies (FE) of Eu²⁺ occupying at FA- (−2.3165 eV), Sn- (−3.2359 eV), and interstitial-site (−6.735 eV) in sequence. (B) Electron localization function (ELF) results of Eu²⁺-incorporated perovskite film. The white dotted box represents a strong interaction between europium and iodide ions. (C) Calculated formation energy of V_{I} without and with Eu²⁺-incorporation. (D) Charge transfer calculated from Bader. (E) The redox property of various ions evaluated from its standard reduction potential (E⁰) in the acid medium. (F) The comparison of E⁰ and ΔG⁰ for reactions. (ΔG⁰=−nFE⁰, where n is the number of electrons transferred in the reaction and F is the Faraday constant) (G) High-resolution XPS spectra of Eu 3d for the Sn⁰—Eu²⁺ incorporated perovskite films after air exposure of 5 hours.

FIG. 3. Characterization of surface properties (A) XPS full spectra. (B, C, and D) High-resolution XPS spectrum: (B) Eu 3d, (C) I 3d and (D) Sn 3d. (E and F) Fitting XPS peaks of Sn 3d: (E) Sn⁰-incorporated and (F) Sn⁰—Eu²⁺ incorporated films. (G) Absorption spectra of the control, Sn⁰-incorporated (blue) and Sn⁰—Eu²⁺ incorporated (reddish orange) samples. The inset shows the Tauc plots calculated by the absorptance spectra. (H) PL spectra of the control (purple), Sn⁰-incorporated and Sn⁰—Eu²⁺ incorporated perovskite films on glass substrates before and after C₆₀ deposition on perovskite films. The corresponding colors of the three perovskite films after C₆₀ deposition are light purple, light blue, and light orange-red.

FIG. 4. Calculation of average electrostatic potential at various positions during charge transfer (A) control sample. (B) Sn⁰—Eu²⁺ incorporated sample. Note that a, b, and c represent the electrostatic potential at different positions. (a) The line represents the electrostatic potential of the electron as it passes through an iodine skeleton with FA present. (b) The line represents the electrostatic potential of the electron as it passes through the inorganic octahedral frame. (c) The rosy dashed line represents the electrostatic potential of the electron as it passes through an Eu²⁺-incorporated iodine skeleton with FA present. (C) The corresponding electron transition energy barrier for two cases. The two E_{F} values were calculated to be −3.5075 eV (control sample) and −4.3441 eV (Sn⁰—Eu²⁺ incorporated sample), respectively.

FIG. 5. Photovoltaic performance and stability (A) Schematic diagram of the energy band levels. (B) J-V curves of the control (purple), Sn⁰-incorporated (blue) and Sn⁰—Eu²⁺ incorporated (red) PSCs. (C) J-V curves, steady-state J_{SC} and maximum power output (measured at a bias of 0.62 V under 100 mW cm⁻² AM 1.5G irradiation) of the Sn⁰—Eu²⁺ incorporated device. (D) Statistical distribution of PCE for control, Sn⁰-incorporated, and Sn⁰—Eu²⁺ incorporated PSCs based on 15 devices. (E) The schematic diagram of fluorescence measurement. (F and G) Normalized PL spectra of the Sn⁰-incorporated and Sn⁰—Eu²⁺ incorporated perovskite films under different illumination time.

FIG. 6. Recombination mechanism in devices (A) Dark J-V curves of the PSC devices. (B) Nyquist plots of the PSC devices. (C) Cross-section SEM image of FASnI₃ device. (D, E and F) J-V with the construction characteristics of hole-only devices of ITO/PEDOT:PSS/Perovskites/PTAA/Au for space charge limited current measurement.

FIG. 7. Optimization of Eu²⁺-incorporated sample concentration (0, 0.5, 1, 2 mol %): (A) XRD patterns of perovskite films w/o and with different amounts of EuI₂. (B) Zoomed-in XRD patterns of corresponding patterns in the regions of 13.0-15.0°. (C) Variation of (100) peak position and FWHM with doping concentration. (D) Williamson-Hall plot showing the variation of relative strain (slope of the fitted curve) with different concentration of EuI₂ dopants. (E) Difference charge density was calculated using a denser Γ-centered 12×16×16 k-point mesh.

FIG. 8. (A) UV-vis absorption spectra. (B) Tauc plots calculated by the absorption spectra. (C) steady-state PL spectra of perovskite films w/o and with different amounts of EuI₂.

FIG. 9. Air stability measurement of (A) control, (B) Sn⁰-incorporated and (C) Sn⁰—Eu²⁺ incorporated thin films: The perovskite films without encapsulation were placed in ambient air for 0, 1, 2, 4, 6, 8 and 10 hours at relative temperature 23±3° C. and relative humid 25=5%. The images on the right showed the aging process. The Sn⁰—Eu²⁺ incorporated film did not only display the strongest diffraction, but also retained the diffraction intensity and film color for a longtime. In contrast, the control and Sn⁰-incorporated films performed relatively lower peak intensity and inferior stability. After the storage of 64 hours, the peak intensity rapidly weakened.

FIG. 10. Air stability measurement of precursor solutions (A, C, E correspond to fresh solutions; B, D, F correspond to aged solutions): Three bottles of precursor solution were exposed to ambient air conditions for two months at a relative temperature of 23±3° C. and a relative humidity of 25±5%. Corresponding photographs of the solutions and SEM images are presented in the inset. The films prepared from the fresh solution exhibited relatively strong diffraction intensity and featured uniform grains with clear boundaries. However, after two months, the solution w/o Sn⁰-w/o EuI₂ turned from yellow to red, and the corresponding SEM image displayed a flocculent shape, indicating the appearance of the SnI₄, as evidenced by the XRD pattern. In contrast, the samples incorporated with Sn⁰ and Sn⁰—Eu²⁺ showed higher FASnI₃ diffraction intensity and maintained a pristine perovskite morphology, along with the corresponding solutions retaining their yellow color.

FIG. 11. (A) XRD patterns of perovskite films on PEDOT:PSS-coated substrates. (B) Zoomed-in XRD patterns of corresponding patterns in the regions of 13.5-29.0°.

FIG. 12. Potential of hydrogen (PH) test: We dripped pure DMSO; Sn⁰-FASnI₃; Sn⁰—Eu²⁺-FASnI₃ solutions onto the PH test paper and compared them with the standard color card. Obviously, the PH-value of FASnI₃ perovskite precursor is less than 7, indicating that the solution is acidic which is beneficial to stabling Sn²⁺.

FIG. 13. High-resolution XPS spectra of (A) Sn 3d and (B) I 3d for the Sn⁰—Eu²⁺ incorporated (upper) and Sn⁰-incorporated (lower) perovskite films, the films were exposed to the air for 5 hours.

FIG. 14. (A) SEM and (B-F) element distribution mapping of Sn⁰—Eu²⁺ incorporated FASnI₃ perovskite film showed the distribution of (C) Sn, (D) Eu, (E) I, (F) Cl elements; Also, the energy-dispersive X-ray spectroscopy (EDS) of Sn⁰—Eu²⁺ incorporated FASnI₃ perovskite thin film (G) and corresponding summary of elemental compositions (H) proved the aforementioned elements.

FIG. 15. Depth-dependent XPS spectra for Eu 3d, the films were etched by argon (Ar⁺) ions at a depth of 0, 40, 80, 120 nm. (A) Sn⁰-incorporated sample and (B) optimized 1 mol % Sn⁰—Eu²⁺ incorporated sample.

FIG. 16. Depth-profile XPS of (A-C) Sn⁰-incorporated and (D-F) Sn⁰—Eu²⁺ incorporated FASnI₃ thin film for Sn 3d_{5/2}.

FIG. 17. Depth-profile XPS of (A, C) Sn⁰-incorporated and (B, D) Sn⁰—Eu²⁺ incorporated FASnI₃ thin film for Sn 3d and I 3d. (etched by argon ions for 0, 40, 80, 120 nm).

FIG. 18. Time-resolved PL spectra of the Sn-perovskite thin films deposited on glass (A) and deposited on PEDOT:PSS (B).

FIG. 19. Ultraviolet photoelectron spectroscopy (UPS) spectra of (A) control, (B) Sn⁰-incorporated and (C) Sn⁰—Eu²⁺ incorporated perovskite films.

FIG. 20. Statistical distribution of (A) V_{OC}, (B) J_{SC}, (C) FF and (D) PCE for control (w/o Sn⁰-w/o EuI₂), Sn (Sn⁰-incorporated) and Sn—Eu (Sn⁰—Eu²⁺ incorporated) PSCs based on 15 devices. The top and bottom error bars in the box charts indicate the highest and the lowest values, respectively.

FIG. 21. External quantum efficiency (EQE) of the control and Sn⁰—Eu²⁺ incorporated FASnI₃ devices.

FIG. 22. Cross-section SEM images of (A) control, (B) Sn⁰-incorporated and (C) Sn⁰—Eu²⁺ incorporated perovskite films deposited on PEDOT:PSS substrates. The scale bar is 250 nm.

FIG. 23. Stability test: (A) Three samples were stored a nitrogen atmosphere; (B) Three samples were exposed to the air for measurement (25±5% relative humidity and 23±33° C.

FIG. 24. J-V curves of the (A-C) control, (D-F) Sn⁰-incorporated and (G-I) Sn⁰—Eu²⁺ incorporated FASnI₃ devices, which were exposed to the AM 1.5G illumination in the glove box for checking ion migration.

FIG. 25. The calculation of lattice parameters. The increased lattice volume from 916.2642 to 920.8437 Å³ when europium occupied at the interstitial-site demonstrated the lattice expansion.

FIG. 26. Charge transfer calculated from Bader.

FIG. 27. The electron transfer reactions and corresponding standard reduction potential (E⁰) and Gibbs free energy (ΔG⁰) in the acid FASnI₃ precursor. (ΔG⁰=−nFE⁰, where n is the number of electrons transferred in the reaction and F is the Faraday constant, the value is 9.6485×10⁴ C/mol).

FIG. 28. PL decay lifetimes (τ₁, τ₂ and τ) of perovskite films without and with Sn⁰—Eu²⁺ doping based on glass substrates. The quoted formula is ξ=τ₁×Rel₁ (%)+τ₂×Rel₂ (%).

FIG. 29 depicts device the structure of an exemplary optoelectronic device comprising the perovskite described herein in accordance with certain embodiments, wherein the optoelectronic device includes a substrate layer (101); a transparent conductive layer (102); a hole-transport layer (103); a perovskite functional layer (104); an electron-transport layer (105); and a metal electrode (106).

### DETAILED DESCRIPTION

### Definitions

The following terms shall be used to describe the present invention. In the absence of a specific definition set forth herein, the terms used to describe the present invention shall be given their common meaning as understood by those of ordinary skill in the art.

Throughout the present specification, unless the context requires otherwise, the word “comprise” or variations such as “comprises” or “comprising”, will be understood to imply the inclusion of a stated integer or group of integers but not the exclusion of any other integer or group of integers. It is also noted that in this disclosure and particularly in the claims and/or paragraphs, terms such as “comprises”, “comprised”, “comprising” and the like can have the meaning attributed to it in U.S. Patent law; e.g., they can mean “includes”, “included”, “including”, and the like; and that terms such as “consisting essentially of” and “consists essentially of” have the meaning ascribed to them in U.S. Patent law, e.g., they allow for elements not explicitly recited, but exclude elements that are found in the prior art or that affect a basic or novel characteristic of the present invention.

Furthermore, throughout the present specification and claims, unless the context requires otherwise, the word “include” or variations such as “includes” or “including”, will be understood to imply the inclusion of a stated integer or group of integers but not the exclusion of any other integer or group of integers.

The use of the singular herein includes the plural (and vice versa) unless specifically stated otherwise. In addition, where the use of the term “about” is before a quantitative value, the present teachings also include the specific quantitative value itself, unless specifically stated otherwise. As used herein, the term “about” refers to a ±10%, ±7%, ±5%, ±3%, ±1%, or ±0% variation from the nominal value unless otherwise indicated or inferred.

The present disclosure provides a perovskite comprising Sn²⁺ and Eu²⁺.

Eu²⁺ and Sn²⁺ can be present in the perovskite at a molar ratio of 0.01:99.99 to 10:90, 0.01:99.99 to 9:91, 0.01:99.99 to 8:92, 0.01:99.99 to 7:93, 0.01:99.99 to 6:94, 0.01:99.99 to 5:95, 0.01:99.99 to 4.5:95.5, 0.01:99.99 to 4:96, 0.01:99.99 to 3.5:96.5, 0.01:99.99 to 3:97, 0.01:99.99 to 2:98, 0.05:99.95 to 2:98.2, 0.5:99.5 to 2:98, 1:99 to 2:98, 1.5:98.5 to 2:98, 0.5:99.5 to 1.5:98.5, 0.5:99.6 to 1:99, 0.6:99.4 to 1.4:98.6, 0.7:99.3 to 1.3:98.7, 0.8:99.2 to 1.2:98.8, or 0.9:99.1 to 1.1:98.9, respectively. In certain embodiments, Eu²⁺ and Sn²⁺ are present in the perovskite at a molar ratio of about 1 to about 99, respectively.

The perovskite can further comprise one or more cations represented by A⁺, wherein A⁺ can be selected from the group consisting of Cs⁺, Rb⁺, CH₃NH₃⁺, CH₃CH₂NH₃⁺, NH₂CH═NH₂⁺, and NH₂C(Me)=NH₂⁺. In certain embodiments, A⁺ is NH₂C(Me)=NH₂⁺.

The perovskite described herein must be charge balanced. Accordingly, the perovskite can further comprise one or more counter ions that balance the charge of the cationic species. Such counter ions are not particularly limited and can be any anion. Exemplary anions include, but are not limited to F⁻, Cl⁻, Br⁻, I⁻, and combinations thereof.

In certain embodiments, the perovskite can be represented by the Formula 1:

(A⁺)(Sn²⁺)(X⁻)₃·m[(Eu²⁺)(Y⁻)₂] 1
wherein m is 0.001-0.1;
X⁻ for each instance is independently F⁻, Cl⁻, Br⁻, or I⁻;
Y⁻ for each instance is independently F⁻, Cl⁻, Br⁻, or I⁻; and
A⁺ is Cs⁺, Rb⁺, CH₃NH₃⁺, CH₃CH₂NH₃⁺, H(C═NH₂)NH₂⁺, Me(C═NH₂)NH₂⁺, or a mixture thereof.

The variable m represents the amount of europium doping in the perovskite described herein and can range from 0.001-0.1, 0.001-0.09, 0.001-0.08, 0.001-0.07, 0.001-0.06, 0.001-0.05, 0.001-0.04, 0.001-0.03, 0.001-0.02, 0.001-0.02, 0.005025-0.0204, 0.0101-0.0204, 0.0152-0.0204, 0.005025-0.0152, 0.00638-0.0142, 0.00753-0.0132, 0.0087-0.0121, 0.0091-0.011, respectively. In certain embodiments, m is about m is about 0.010101. In certain embodiments, m corresponds to a molar ratio of Eu²⁺ and Sn²⁺ of 0.5:99.6 to 1:99, 0.6:99.4 to 1.4:98.6, 0.7:99.3 to 1.3:98.7, 0.8:99.2 to 1.2:98.8, or 0.9:99.1 to 1.1:98.9, respectively.

In certain embodiments, A⁺ is H(C═NH₂)NH₂⁺, Me(C═NH₂)NH₂⁺, or a mixture thereof. In certain embodiments, A⁺ is H(C═NH₂)NH₂⁺.

In certain embodiments, each of X⁻ and Y⁻ is I.

In certain embodiments, the perovskite is represented by the Formula 2:

(H(C═NH₂)NH₂⁺)(Sn²⁺)(I⁻)₃·m[(Eu²⁺)(I⁻)₂]

wherein m is about 0.010101.

The perovskite described herein can be prepared from a perovskite precursor solution comprising one or more tin salts, EuY₂, AZ, optionally tin powder, and a solvent, wherein the one or more tin salts is represented by the formula SnX₂, A is Cs⁺, Rb⁺, CH₃NH₃⁺, CH₃CH₂NH₃⁺, H(C═NH₂)NH₂⁺, Me(C═NH₂)NH₂⁺, or a mixture thereof, X for each instance is independently F⁻, Cl⁻, Br⁻, I⁻, or a mixture thereof, Y for each instance is independently F⁻, Cl⁻, Br⁻, I⁻, or a mixture thereof, Z is F⁻, Cl⁻, Br⁻, or I⁻, and the solvent comprises dimethyl formamide (DMF), dimethyl sulfoxide (DMSO), or a mixture thereof.

The one or more tin salts can be present in the perovskite precursor solution at a concentration from 0.5 to 1.5 M, 0.6 to 1.5 M, 0.7 to 1.5 M, 0.8 to 1.5 M, 0.9 to 1.5 M, 1.0 to 1.5 M, 1.1 to 1.5 M, 1.2 to 1.5 M, 1.3 to 1.5 M, 1.4 to 1.5 M, 0.5 to 1.4 M, 0.5 to 1.3 M, 0.5 to 1.2 M, 0.5 to 1.1 M, 0.5 to 1.0 M, 0.5 to 0.9 M, 0.5 to 0.8 M, 0.5 to 0.7 M, 0.5 to 0.6 M, 0.6 to 1.4 M, 0.7 to 1.3 M, 0.8 to 1.2 M, or 0.9 to 1.1 M. SnI₂ can be present in the perovskite precursor with a concentration ranging from 0.9 to 1.1 M, while SnCl₂ is introduced at concentrations varying from 0.09 M to 0.22 M. In certain embodiments, SnI₂ and SnCl₂ are present in the perovskite precursor solution at a concentration of about 0.9 M and about 0.093 M, respectively.

Oxidation of Sn²⁺ in the perovskite precursor solution can be suppressed by the addition of one or more of Sn powder and SnF₂ to the perovskite precursor solution. Sn powder can be present in the perovskite precursor solution with a concentration ranging from 0.04 to 0.8 M, 0.1 to 0.8 M, 0.2 to 0.8 M, 0.3 to 0.8 M, 0.4 to 0.8 M, 0.5 to 0.8 M, 0.6 to 0.8 M, 0.7 to 0.8 M, 0.04 to 0.7 M, 0.04 to 0.6 M, 0.04 to 0.5 M, 0.04 to 0.4 M, 0.04 to 0.3 M, 0.04 to 0.2 M, 0.04 to 0.1 M, 0.2 to 0.7 M, 0.3 to 0.6 M, or 0.4 to 0.5 M. SnF₂ can be present with a concentration ranging from 0.09 to 0.11 M. In certain embodiments, SnF₂ is present in the perovskite precursor solution at a concentration of about 0.09 M.

In certain embodiments, the perovskite precursor solution further comprises ethanediamine dihydroiodide (EDADI).

The solvent can be any solvent in which the one or more salts and AZ are least partially soluble. In certain embodiments, the solvent is a polar aprotic solvent. Exemplary solvents include, but are not limited to dimethyl sulfoxide (DMSO), dimethylformamide (DMF), dimethylacetamide (DMAc), N-methyl-2-pyrrolidone (NMP), and mixtures thereof. In certain embodiments, the solvent comprises DMSO.

The perovskite described herein can be prepared by depositing the perovskite precursor solution on a substrate thereby forming an unannealed perovskite thin film and annealing the unannealed perovskite thin film thereby forming the perovskite.

The perovskite precursor solution can be deposited on the substrate using any method known to those of skill in the art including, but not limited to, spin coating, printing, print screening, spraying, painting, doctor-blading, slot-die coating, and dip coating.

The unannealed perovskite thin film can be annealed at 40-150° C., 40-125° C., 40-100° C., 50-90° C., 60-80° C., or 65-75° C. In certain embodiments, the unannealed perovskite thin film is annealed at about 70° C.

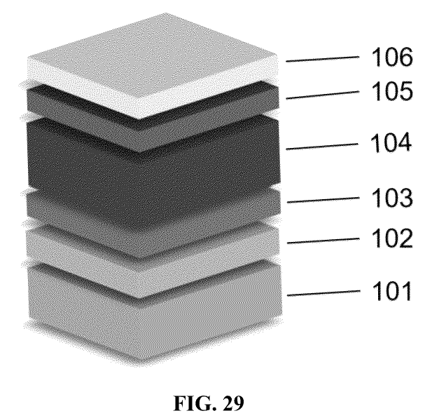

The present disclosure also provides electronic devices comprising the perovskite described herein. Referring to FIG. 29, the electronic device can comprise: a substrate layer (101); a transparent conductive layer (102) disposed on a surface of the substrate layer (101), a hole-transport layer (103) disposed on the surface of the substrate layer (102); a perovskite functional layer (104) comprising the perovskite described herein disposed on a surface of the hole-transport layer (103); an electron-transport layer (105) disposed on the surface of the perovskite functional layer (104); and a metal electrode (106) disposed on the surface of the electron-transport layer (105).

The substrate (101) can comprise a flexible or rigid material with light transmittance greater than 80% (at 550 nm). In certain embodiments, the substrate comprises: polymethyl methacrylate (PMMA), polycarbonate (PC), polystyrene, (PS), polyethylene glycol terephthalate, (PET), polyethylene naphthalate (PEN), polydimethylsiloxane (PDMS), styrene-ethylene-butylene-styrene (SEBS), ethylene terephthalateco-1,4-cylclohexylenedimethylene terephthalate (PETG), acrylonitrile butadiene styrene copolymers (ABS), polypropylene (PP), polyamide (PA) acrylonitrile-styrene copolymer (AS), or mixtures thereof.

The transparent conductive layer (102) can comprise aluminum- or indium-doped zinc oxide, magnesium-indium oxide, nickel-tungsten oxide, gallium nitride, zinc selenide, zinc sulfide, zinc oxide (ZnO), tin oxide (SnO₂), lithium fluoride (LiF), zinc indium tin oxide (ZITO), indium tin oxide (ITO), aluminum zinc oxide (AZO), fluorine tin oxide (FTO), graphene, poly(3,4-ethylenedioxythiophene) polystyrene sulfonate (PEDOT:PSS), silver nanowire, copper nanowire, or a mixture thereof.

The hole-transport layer (103) can comprise SAMs (self-assembled monolayer), PTAA (poly (triaryl amine), PTAA), PEDOT:PSS, NiOₓ, Spiro-OMeTAD, or mixtures thereof.

The perovskite functional layer (104) comprises a perovskite described herein.

The electron-transport layer (105) can comprise PC₆₁BM, C60, SnO₂, or a mixture thereof.

The metal electrode can comprise any metal with resistivity less than 5×10⁻⁷ Ω·m (at 25° C.). Exemplary metal electrode metals include, but are not limited to Ag, Cu, Au, Al, W, Fe, Pt, and mixtures thereof.

In another aspect, the present application provides a method for fabricating the electronic device. In certain embodiments, HTL material is spin-coated on the (102) transparent conductive layer and annealed thereby forming the hole-transport layer (103). Then, the perovskite percursor solution is spin-coated on the (103) hole-transport layer, and the (104) perovskite functional layer is formed after annealing. ETL materials and metal electrode materials are sequentially evaporated on the (104) perovskite functional layer by vacuum thermal evaporation to complete the device preparation.

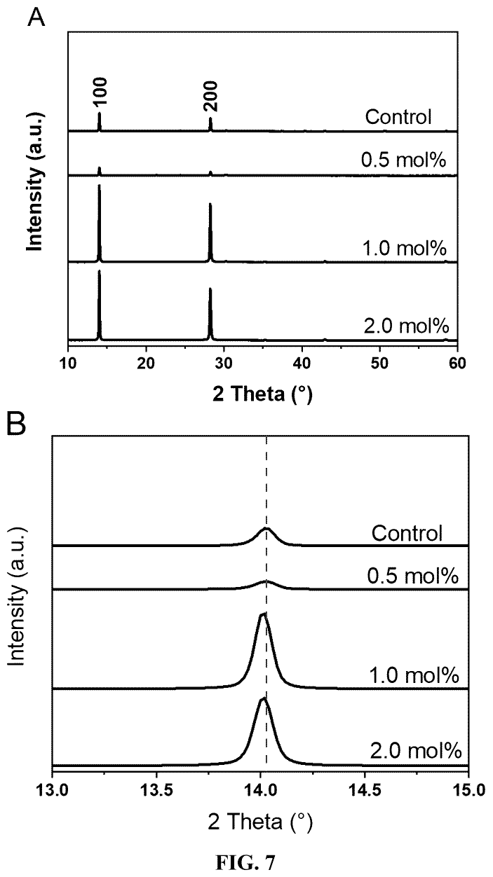

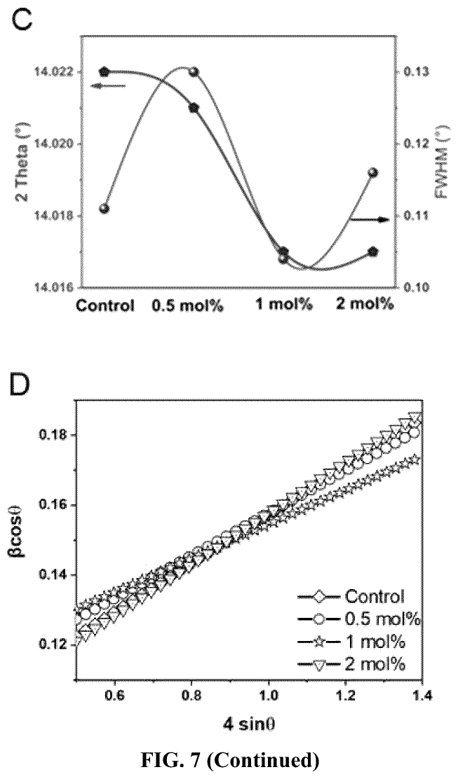

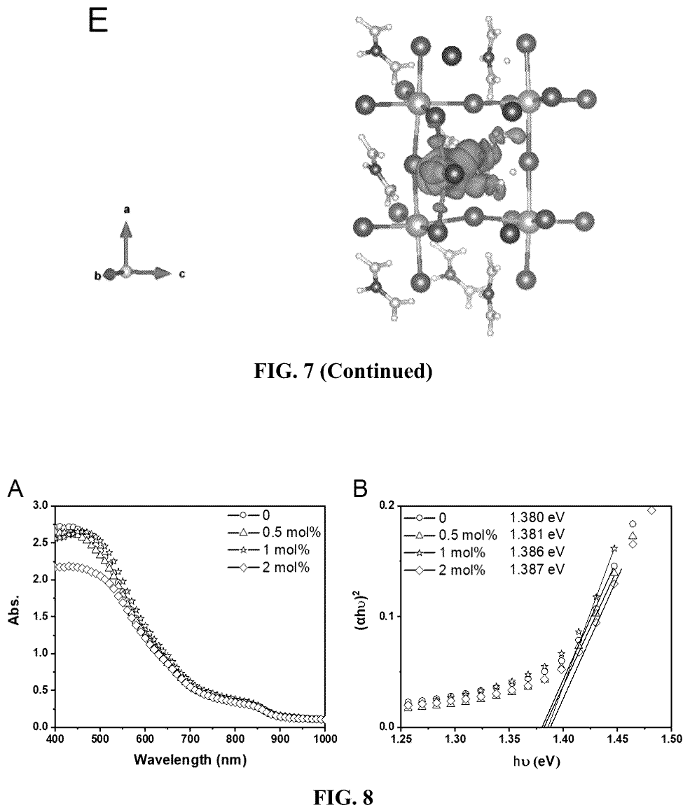

For the synthesis of perovskite film samples, europium dopants (EuI₂) with different concentrations (0, 0.5, 1.0 and 2.0 mol %) were incorporated into FASnI₃ (FA=NH₂CH═NH₂⁺) precursor solutions, following by 0.1 g/ml Sn metallic powder as a solution-oxidation resistor. FIG. 7A and FIG. 7B showed the X-ray diffraction (XRD) patterns of FASnI₃ perovskite films with different amounts of EuI₂. The (100) and (200) diffraction peaks gradually shift to lower 20 angles with the doping concentration, indicating a lattice expansion of the Eu²⁺-doped samples. These results suggested that Eu has entered into the FASnI₃ lattice, most likely as interstitials. Furthermore, the full width at half maximum (FWHM) in XRD patterns suggested the optimum crystallinity for the samples with 1 mol % EuI₂ due to the lowest FWHM value (FIG. 7C). It is worth noting that lattice structure in tin-based perovskites generally exhibits strain and disorder, owing to the rapid crystallization process as well as the hydrogen bonding induced octahedral tilting and local asymmetry. To investigate the effect of Eu²⁺ on the lattice strain of FASnI₃ perovskites, the lattice micro-strain (ε) was calculated by the Williamson-Hall plot from XRD patterns (FIG. 7D). We discovered that the optimum incorporation of Eu²⁺ caused the decrease of ε value and thereby the relief of lattice strain. This is attributed to the interaction between Eu²⁺ and FA⁺ that can counteract the hydrogen bonding attraction between FA⁺ and the octahedra, evidenced by the DFT calculations in FIG. 7E.

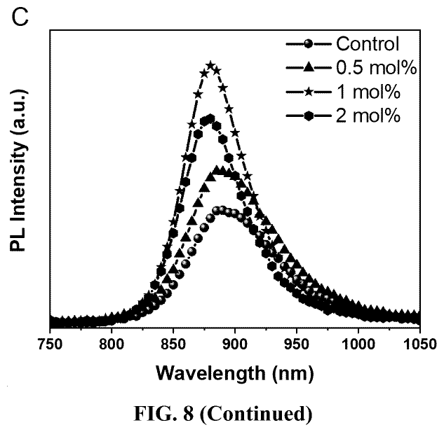

The ultraviolet-visible (UV-vis) absorption and steady-state photoluminescence (PL) spectra of the perovskite films were further used to check the optimum concentration of Eu²⁺ (FIG. 8). The band gaps (E_{g}) derived from the Tauc plots in FIG. 8B were calculated to be 1.380 eV (control), 1.381 eV (0.5 mol %), 1.386 eV (1.0 mol %) and 1.387 eV (2.0 mol %), respectively, indicating a gradual blue shift of bandgap with the increasing concentration of EuI₂ dopants, which is consistent with the results from XRD analysis. Similarly, the steady-state PL peak consistently blue-shifts to a shorter wavelength, with the maximum intensity observed when the Eu²⁺ concentration was 1 mol % (FIG. 8C). Such significant increase in PL intensity is ascribed to the reduced micro-strain and in-gap traps in the EuI₂ doped perovskite film, contributing consequently to the reduced nonradiative recombination. Based on all above results, we consider 1 mol % as the optimal doping concentration, which is adopted in the following studies.

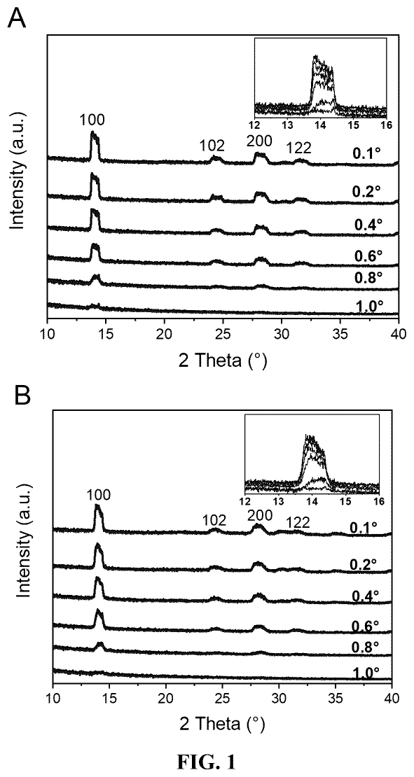

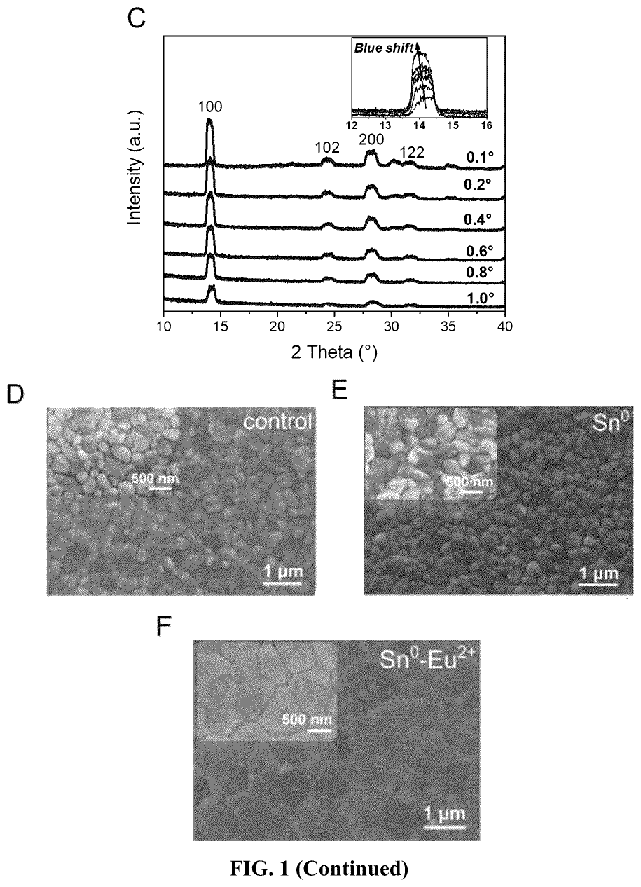

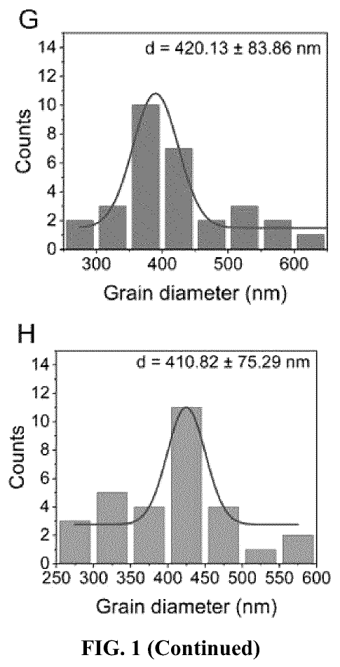

As noted above, metallic Sn powders are added in Sn perovskite precursor solutions due to a synergistic effect originated from Sn⁰ and Eu²⁺. As confirmed in the literature, Sn powders can reduce a high concentration of Sn⁴⁺ in the Sn perovskite precursor solution. The addition of an optimal amount of EuI₂ (1 mol %) is expected to further reduce Sn⁴⁺ and inhibit the formation of neutral iodine (I⁰). To confirm this, we focused on the comparison among three samples (control: without the addition of Sn powder or EuI₂; Sn⁰-incorporated: with the addition of Sn powder but not EuI₂; Sn⁰—Eu²⁺ incorporated: with the addition of both Sn powder and EuI₂). FIGS. 1A-C showed depth-dependent grazing incidence X-ray diffraction (GIXRD) patterns, which reveal the perovskite structure from the top surface to the bulk regions within the perovskite films. The overall diffraction peak intensity of the control or Sn⁰-incorporated sample is much lower than that of the Sn⁰—Eu²⁺ incorporated sample. In addition, there is no notable alteration in the lattice constant of control and Sn⁰-incorporated samples as the glancing angle increases (See the inset of FIGS. 1A-B). Whereas the diffraction peak assigned to (100) plane gradually shifted to lower angle upon the additional introduction of 1 mol % EuI₂, demonstrating the Eu²⁺ into the perovskite lattice (FIG. 1C). More importantly, there is a notable improvement in crystallization observed in the near-surface region of the Sn⁰—Eu²⁺ incorporated sample. We suggest that, in addition to Eu²⁺ ions incorporated into the lattice, a small fraction of Eu²⁺ are distributed at the grain-boundary of perovskite films, possibly serving as surface passivation with the effect on surface morphology.

The scanning electron microscope (SEM) was employed to depict the surface morphology of different thin films (FIGS. 1D-F). The control film displayed a relatively rough morphology with noticeable pinholes and grain boundaries. The Sn⁰-incorporated film exhibited relatively dense grain distribution, which may be attributed to the antioxidative properties of Sn powder, suppressing the formation of Sn vacancy defects. In contrast, the Sn⁰—Eu²⁺ incorporated film exhibited a compact, uniform, and pinhole-free morphology. Based on statistical measurement results in FIG. 1G-I, the average grain sizes for the three samples are 420 nm (control), 410 nm (Sn⁰ incorporated), and 825 nm (Sn⁰—Eu²⁺ incorporated), respectively. The significantly improved morphology and increased grain size observed in the Sn⁰—Eu²⁺ incorporated film can be ascribed to the modification of the surface energy during crystal growth through the introduction of Eu²⁺ ions, thereby promoting a more oriented crystal growth process, resulting in larger grain sizes and enhanced crystalline quality.

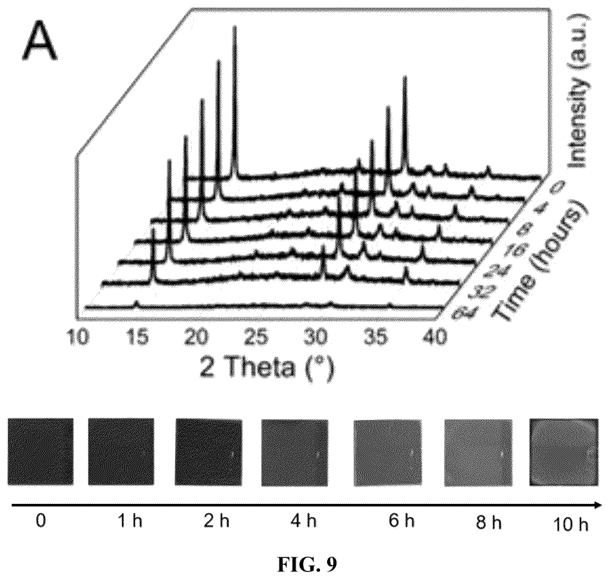

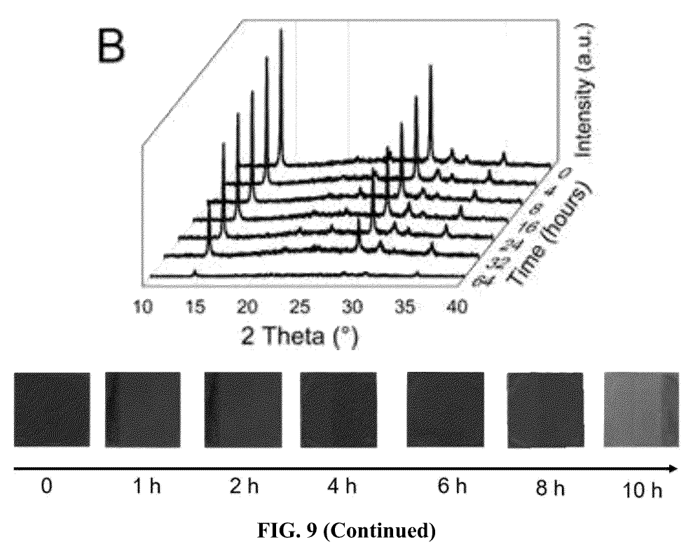

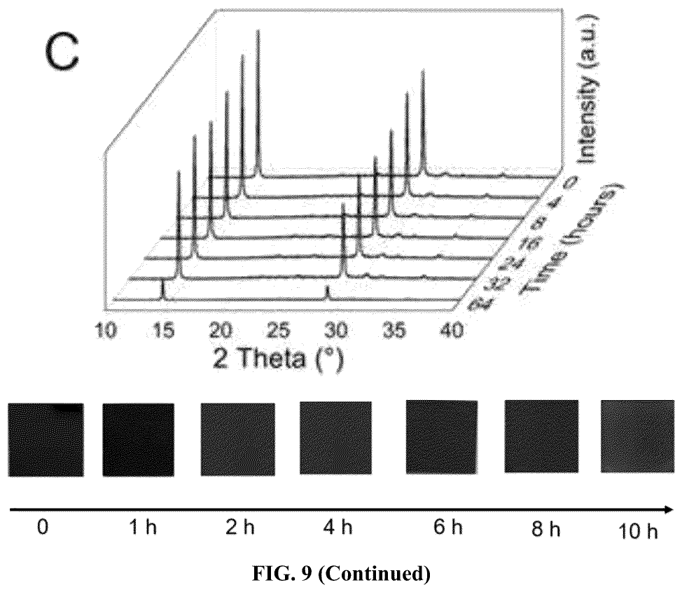

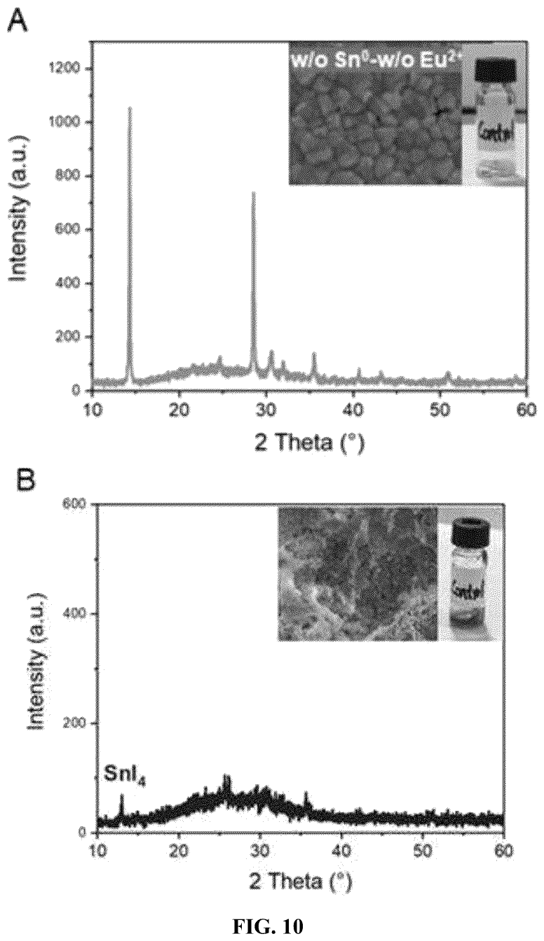

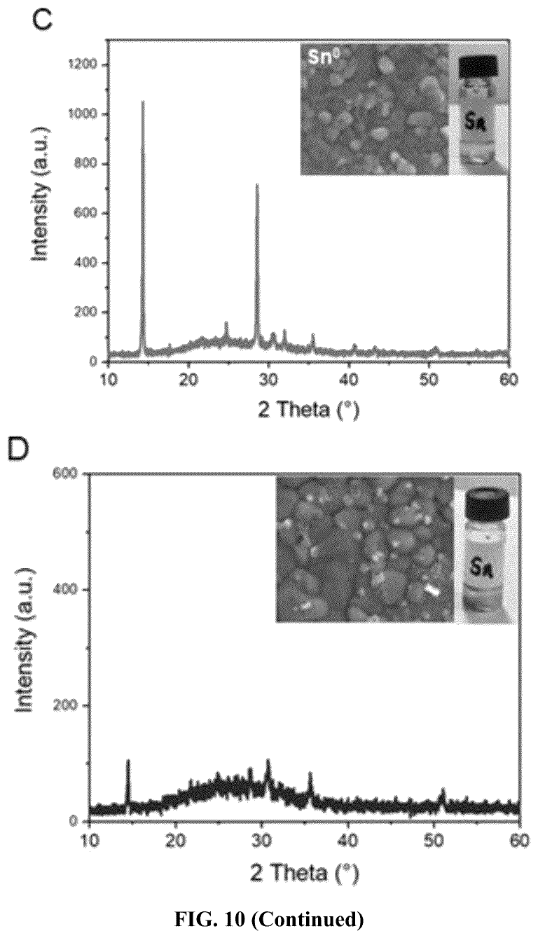

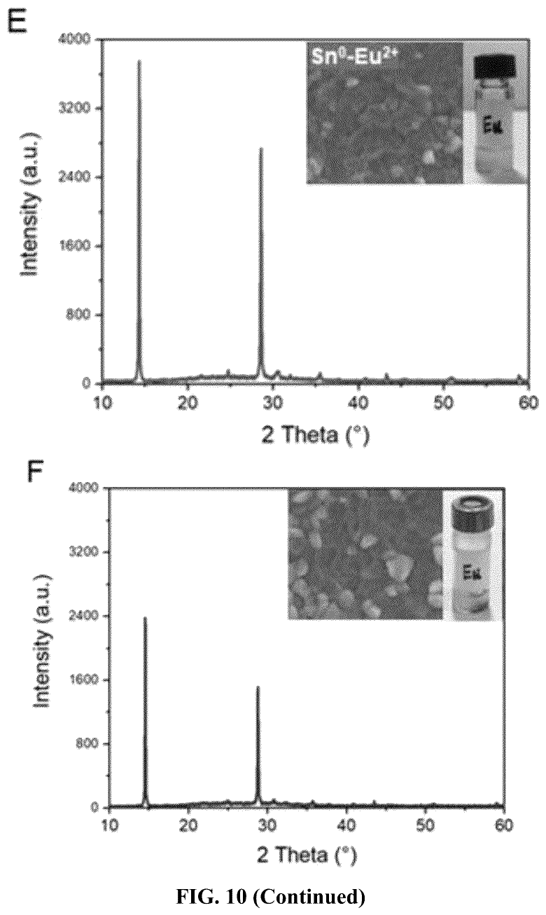

The improved morphology of thin films contributes to shielding perovskite materials from degradation caused by humidity in air. We thus exposed the prepared thin film samples to air for 10 hours (FIG. 9). A significantly faster lattice degradation was observed in the control samples. By incorporating Sn⁰ and EuI₂, we could enhance the maintenance of lattice and effectively prevent lattice collapse. It is worth noting that the simultaneous doping of Sn⁰ and Eu²⁺ can further enhance the anti-degradation ability of the films. Furthermore, three samples of perovskite solutions were subjected to a two-month aging experiment in air to evaluate the influence of Eu²⁺ in the solution (FIG. 10). In comparison with the Sn⁰ and Sn⁰—Eu²⁺ incorporated solutions, the control one exhibited a darker color and thereby a fibrous morphology in resulting films, suggesting a high concentration of Sn⁴⁺ in the solution, evidenced further by the XRD analysis in FIG. 10B. Adding Sn⁰ powder alone could not effectively suppress the Sn²⁺ oxidation due to the obvious deterioration after two months of solution aging. Whereas high-quality perovskite films with well-preserved crystal structures were successfully obtained with the subsequent addition of EuI₂.

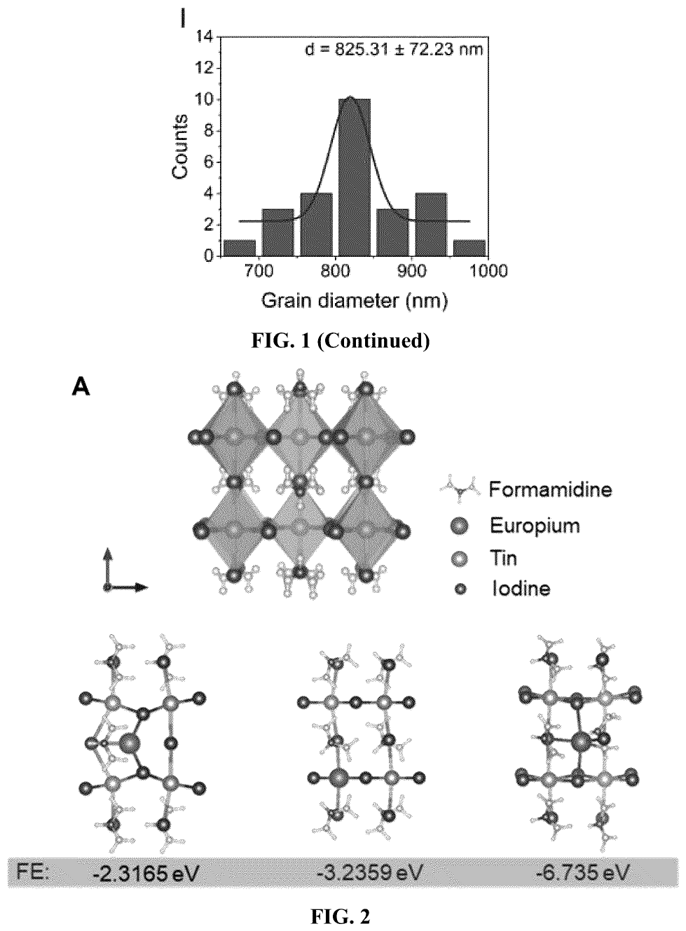

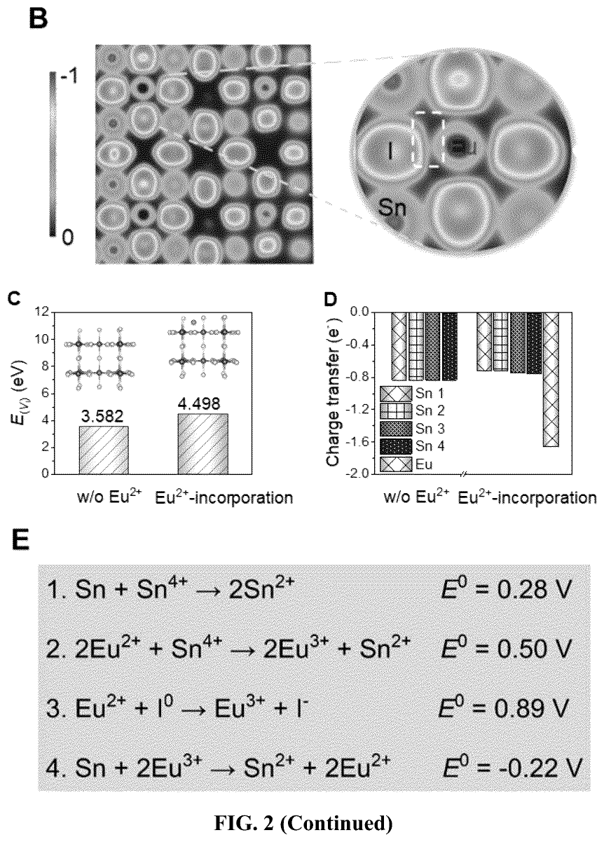

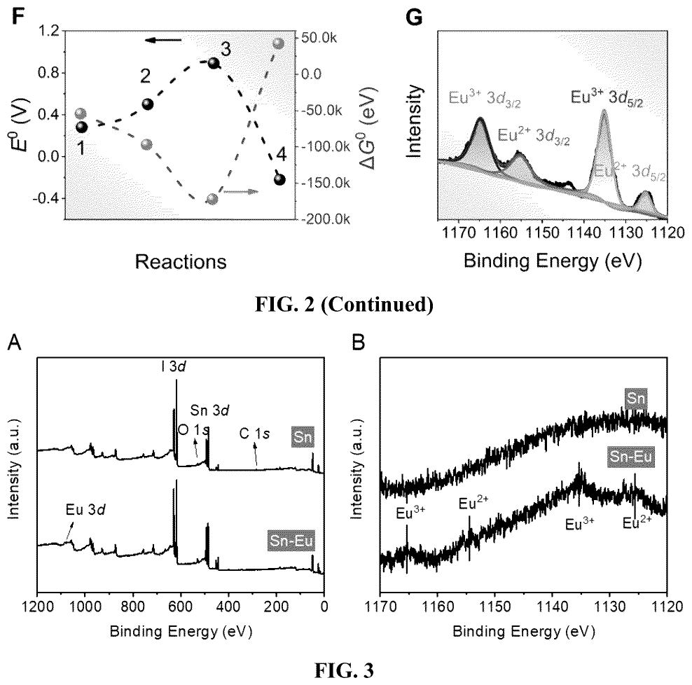

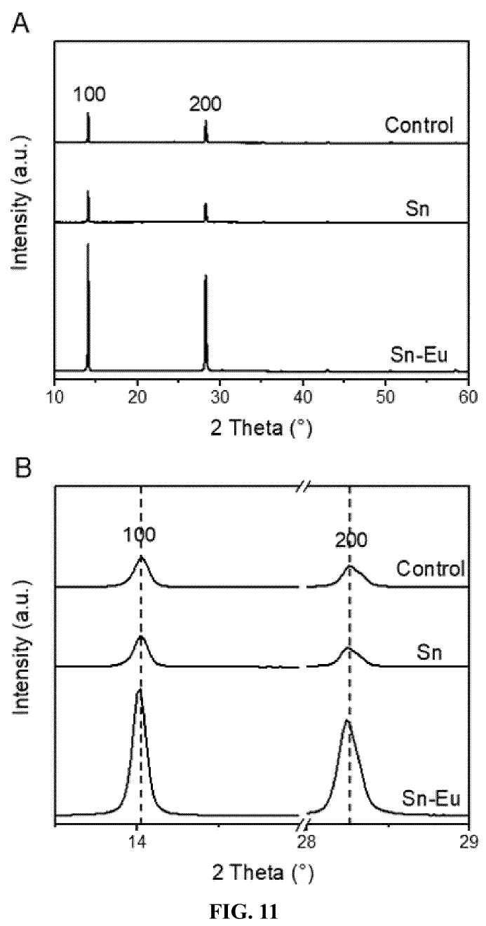

Given that Eu²⁺ (109 pm) or Eu³⁺ (95 pm) ions have larger radii than Sn²⁺ (93 pm) but smaller than FA⁺ (253 pm), it's likely that the lattice expansion resulted from Eu²⁺ ions occupying either the Sn sites or interstitial positions in the FASnI₃ lattice (FIG. 11 and FIG. 25). FIG. 2A depicted the FASnI₃ perovskite crystal structure and the corresponding formation energies (FE) of Eu²⁺ insertion in the FA-site (with values of −2.3165 eV), Sn-site (−3.2959 eV), and interstitial site (−6.735 eV). The lowest FE was observed when Eu²⁺ was inserted at the interstitial site, indicating its predominant occupancy there. The electron localization function (ELF) analysis in FIG. 2B confirmed the transfer of electrons from Eu to I atoms, potentially impeding the formation of iodide vacancies (V_{I}), which are known as significant defects in Sn-based perovskites. Upon introducing Eu²⁺, the FE of V_{I} defects increased from 3.582 eV to 4.4983 eV, resulting in an increased energy barrier for I⁻ ion migration, as depicted in FIG. 2C. The charge density distribution of Eu²⁺ in FIG. 7E revealed that Eu²⁺ could stabilize thermally unstable organic components, enhancing structural robustness and lattice stability when doping Eu²⁺ in interstitial positions. Moreover, we analyzed the charge transfer around europium and tin through Bader charge distributions, and found that europium showed greater electron loss and easier oxidation compared to tin (FIG. 2D, detailed parameters in FIG. 26).

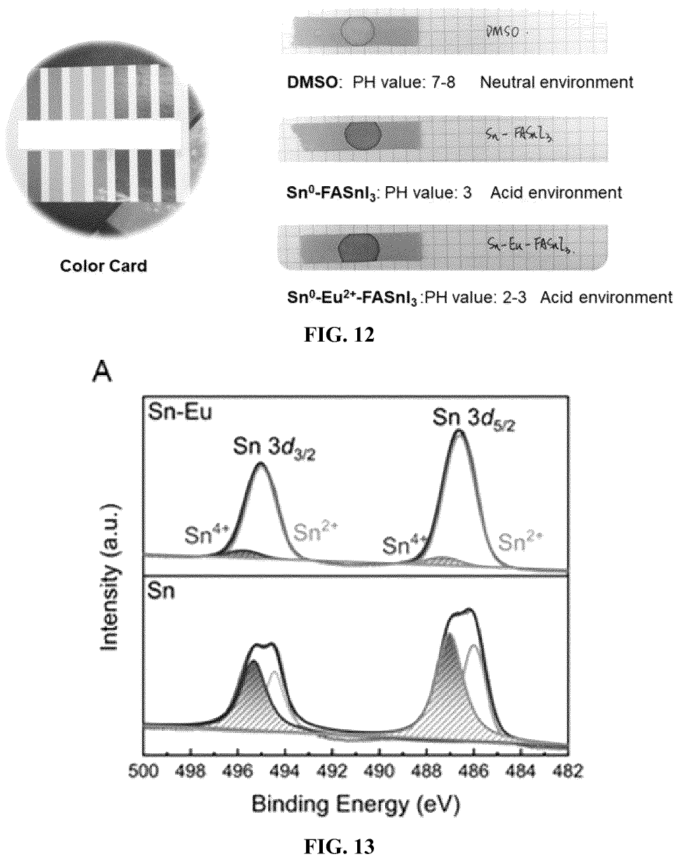

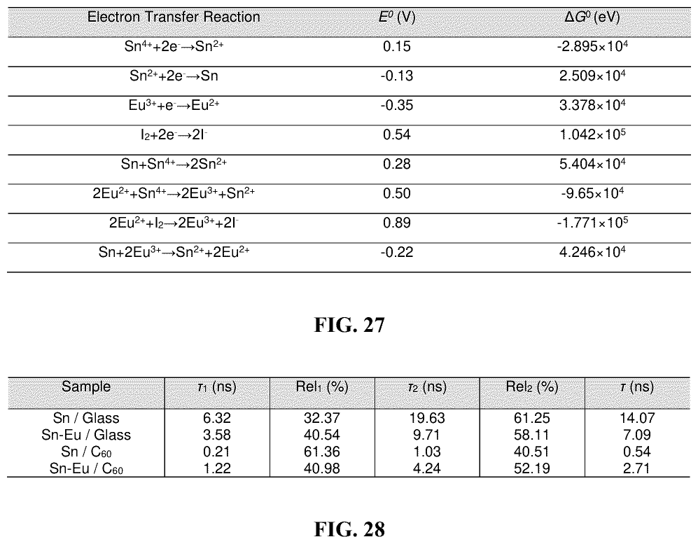

The redox properties of Sn⁰ and Eu²⁺ can be assessed through solvent-dependent standard reduction potential (E⁰) in either alkali or acidic environments. When dissolved in the neutral solvent of dimethyl sulfoxide (DMSO), FASnI₃ perovskite exhibits acidic behavior (see FIG. 12), which promotes the stabilization of Sn²⁺. In FIG. 2E, we outlined four potential reactions in the acidic precursor and compared their E⁰ values in FIG. 2F (calculated from FIG. 27). As shown in FIG. 2F, reaction 3 possesses the highest E⁰ value, signifying that Eu²⁺ primarily serves as a reducing agent for 1°. It's worth nothing that Eu²⁺ exhibits a stronger reducing capability than that of Sn powders, demonstrating its effectiveness in reducing Sn⁴⁺. Gibbs free energy change (ΔG⁰=nFE⁰, where n represents the number of electrons transferred in the reaction, and F is the Faraday's constant) serves as a criterion for assessing the thermodynamic favorability of reactions. Due to their negative ΔG⁰ values, reactions 1, 2, and 3 occur spontaneously while reaction 4 is determined to be thermodynamically unfavorable. As a result, Eu²⁺, as an electron donor, can create a reducing environment to suppress the formation of V_{Sn} and V_{I}.

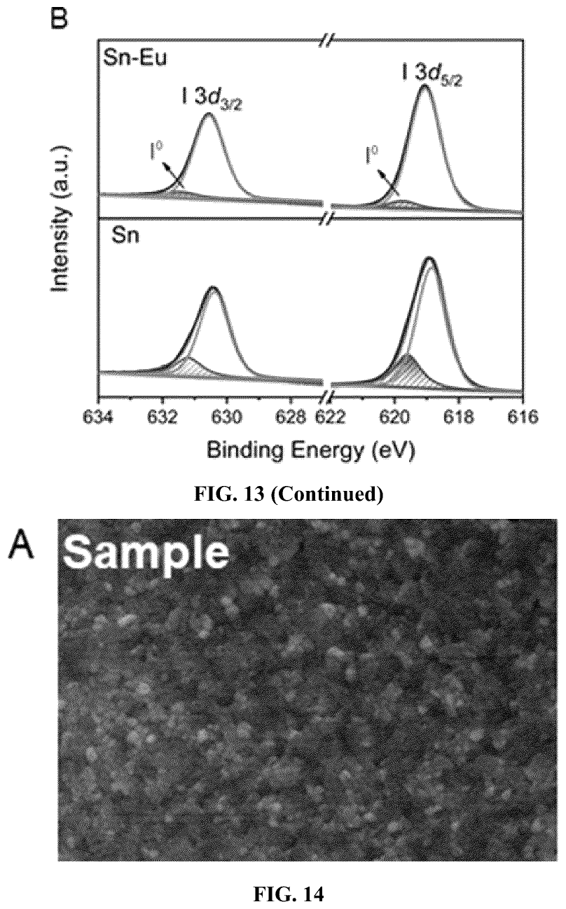

To assess the oxidation resistance of Eu²⁺, we prepared perovskite films using aged precursors incorporated with Sn⁰ and Sn⁰—Eu²⁺, followed by X-ray photoelectron spectroscopy (XPS) measurements. Sn²⁺ tends to be more stable in EuI₂-doped precursors, as evidenced by the lower content of Sn⁴⁺ in FIG. 13A. Previous reports have indicated that I⁰ is a byproduct of hydrolysis of hydroiodic acid and a degradation product of SnI₄. The Sn⁰—Eu²⁺ incorporated film showed less I⁰ than that the Sn⁰-incorporated sample (FIG. 13B), demonstrating Eu²⁺ could simultaneously act as a reducing agent for I⁰. In FIG. 2G, Eu³⁺ peaks were observed at 1164.9 eV and 1135.2 eV, respectively, while Eu²⁺ peaks were detected at 1155.1 eV and 1125.3 eV, respectively. The generation of Eu³⁺ is more likely to be attributed to redox reactions between Eu²⁺, Sn⁴⁺ and I⁰, as its negative ΔG⁰ value.

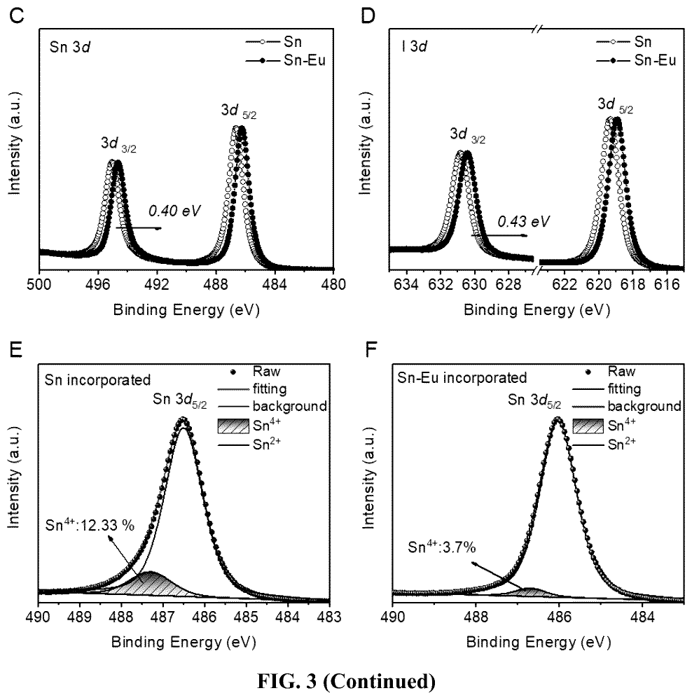

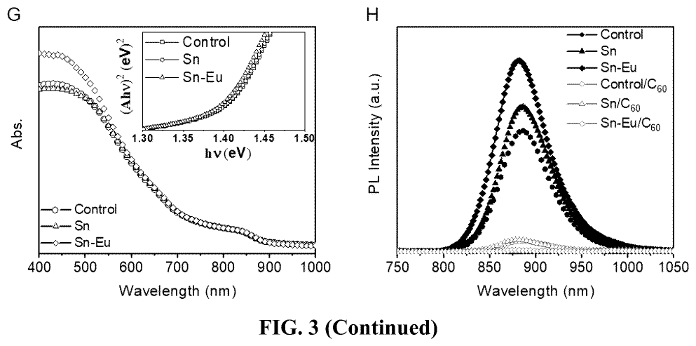

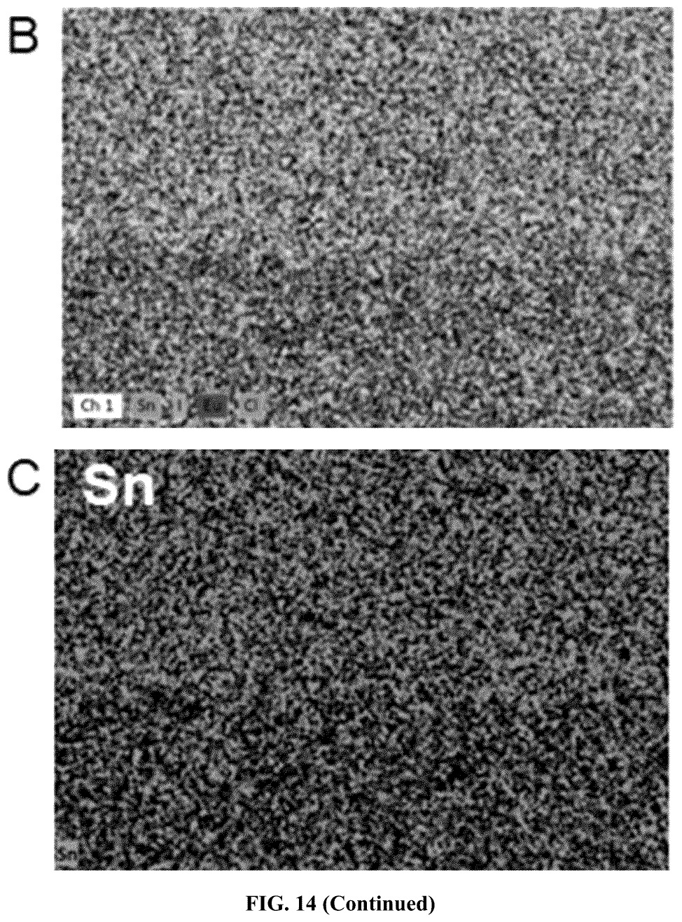

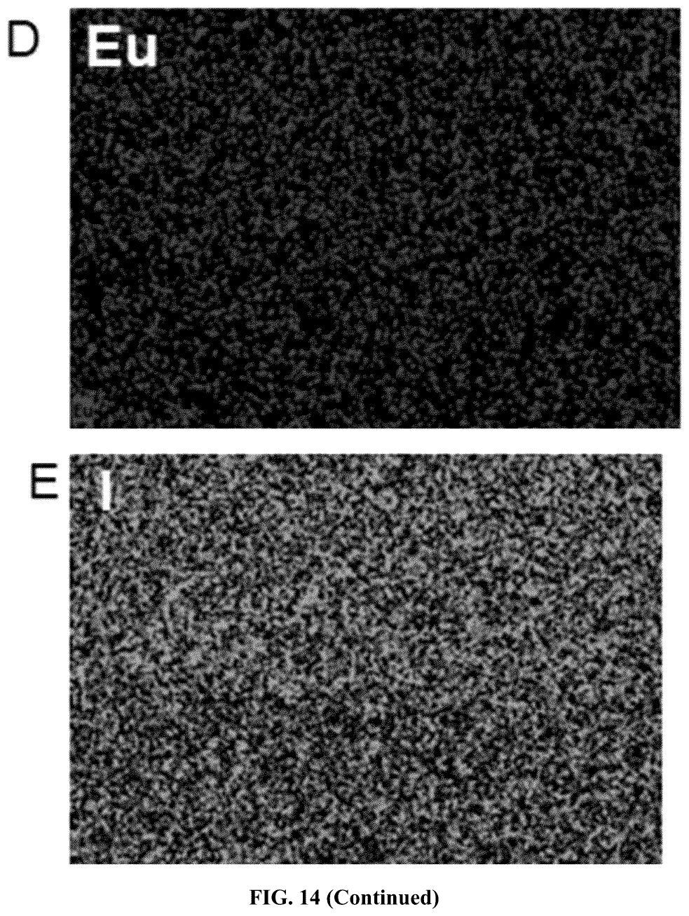

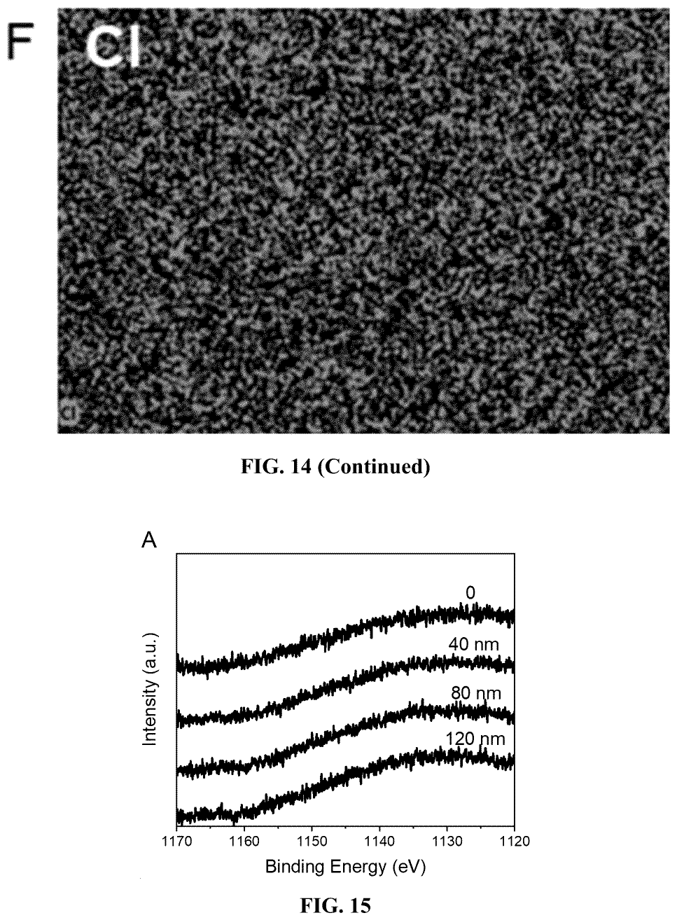

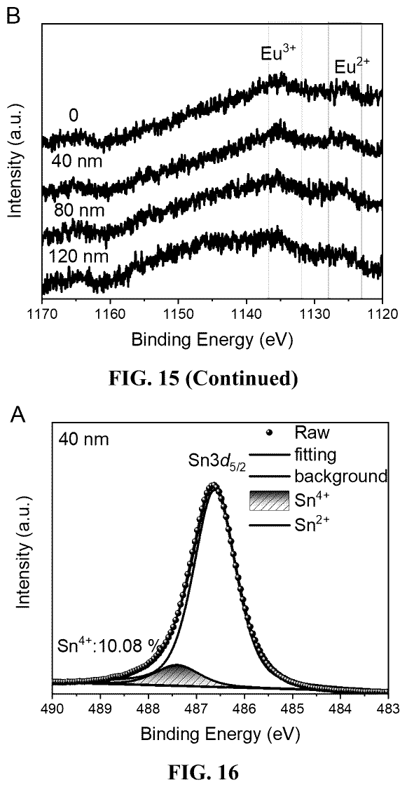

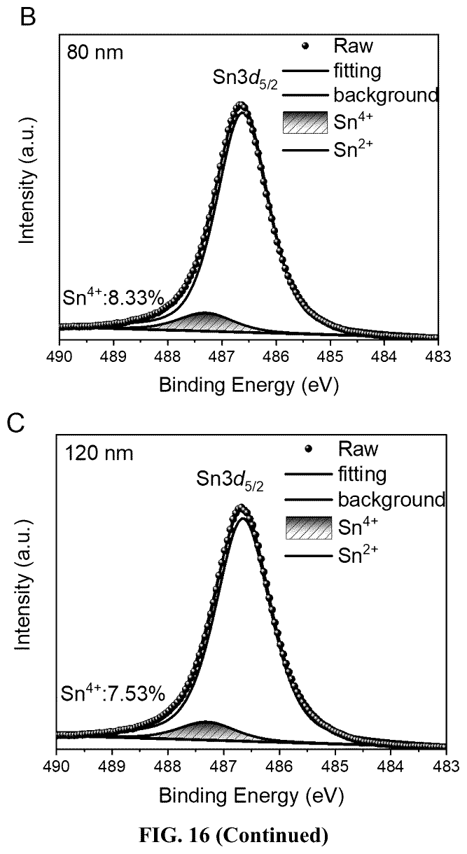

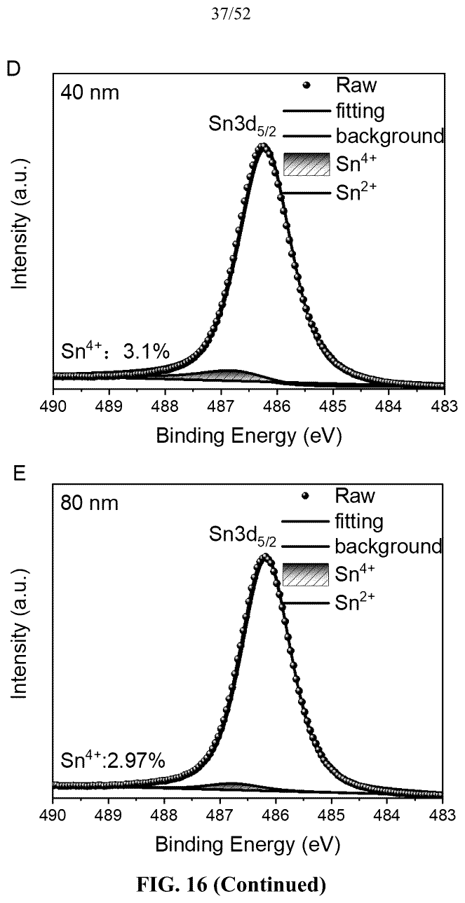

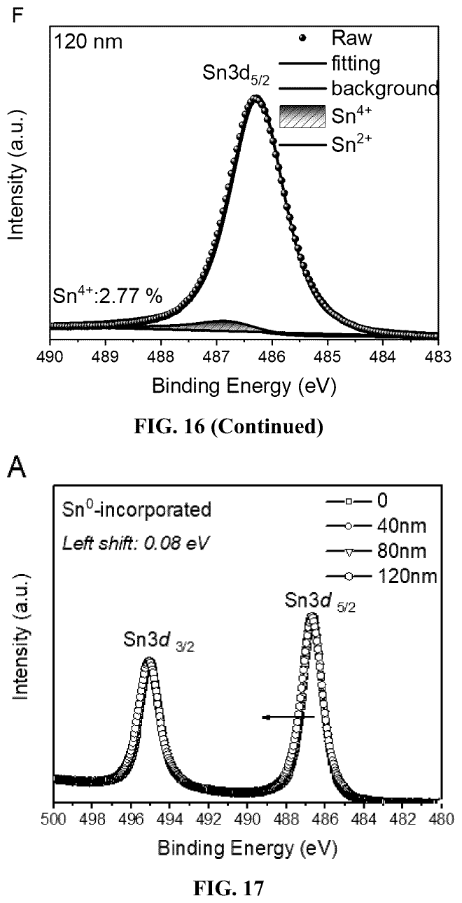

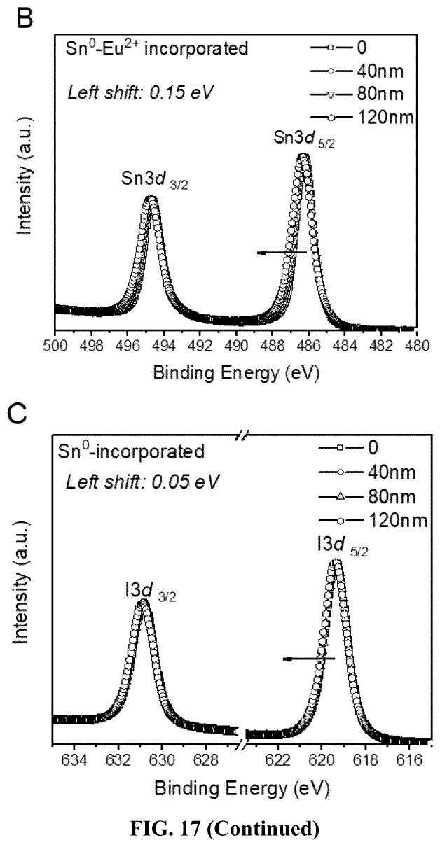

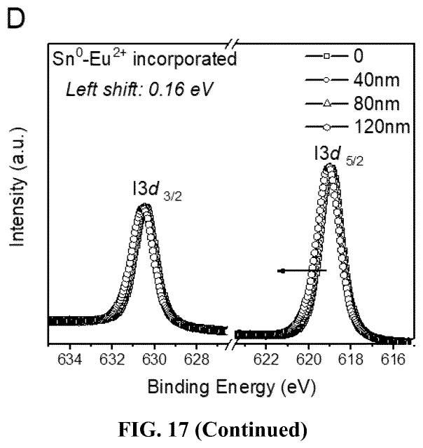

We conducted energy-dispersive X-ray spectroscopy (EDS) mapping on the Sn⁰—Eu²⁺ incorporated sample (FIG. 14) to analyze the Eu distribution. The maps showed a uniform surface distribution of Eu, constituting 0.63% of the atomic mass. FIG. 3A displayed the XPS full spectra for two fresh samples, with a magnified view of the Eu peaks in FIG. 3B. Simultaneously emerging small peaks represented Eu²⁺ and Eu³⁺, which could be attributed to continuous redox reactions with Sn⁴⁺ and I⁰ defects. This is also supported by the shifts in the E_{B} peaks for I (0.40 eV) and Sn (0.43 eV) towards lower values after Eu²⁺ doping, as shown in FIGS. 3C and 3D. Such shift can be attributed to the reduction of Sn and I's oxidation state, which is likely a result of electron donation from Eu²⁺ through a reduction process. The depth-dependent XPS measurements were further performed to evaluate the oxidation process inside the perovskite layer by sputtering the samples with argon ions (Ar⁺) to different depths (0, 40, 80, and 120 nm). Eu²⁺ exhibited gradient doping, with signal intensity decreasing as sputtering depth increased (FIG. 15). FIG. 3E-F reveals that the Sn⁴⁺ content at the surface of the Sn⁰—Eu²⁺ incorporated sample was merely 3.7%, significantly lower than 12.33% in the Sn⁰-incorporated sample. This disparity persisted as the sputtering depth increased, that a lower Sn⁴⁺ content was observed for Sn⁰—Eu²⁺ incorporated sample (FIG. 16). Additionally, we noted shifts toward higher values in the E_{B} peaks of Sn and I in both samples as the sputtering depth increased (FIG. 17). Specifically, the XPS peaks for Sn 3d and I 3d shifted by 0.08 eV and 0.05 eV for the Sn⁰-incorporated sample, and by 0.15 eV and 0.16 eV for the Sn⁰—Eu²⁺ incorporated sample, respectively. We speculated the introduction of Eu²⁺ into the perovskite lattice engendered alterations in the chemical environment of the [SnI₆]⁴⁻ octahedron, resulting in marked shifts in the XPS peaks upon EuI₂ doping.

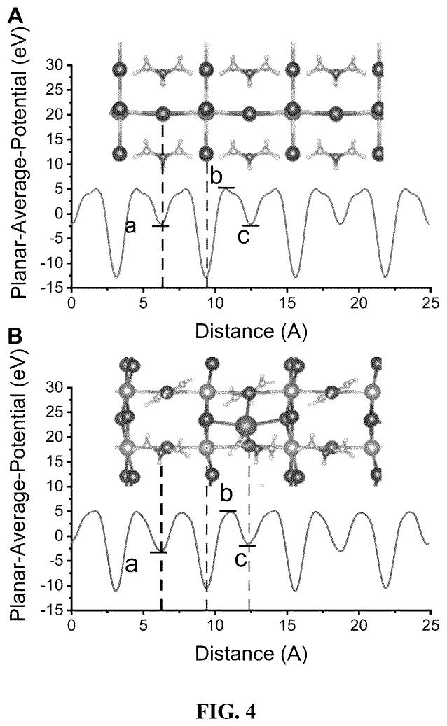

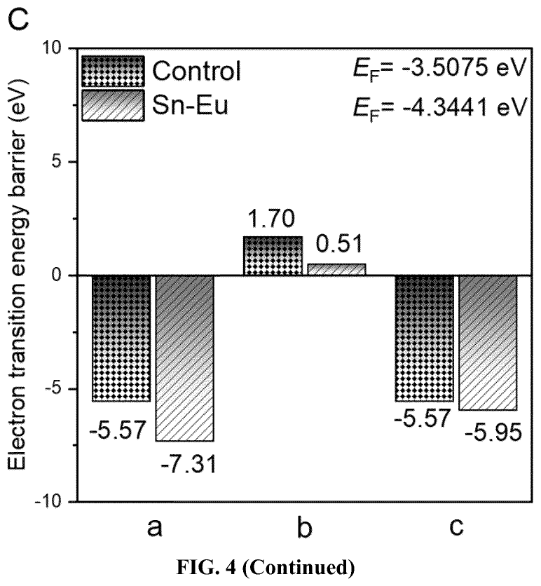

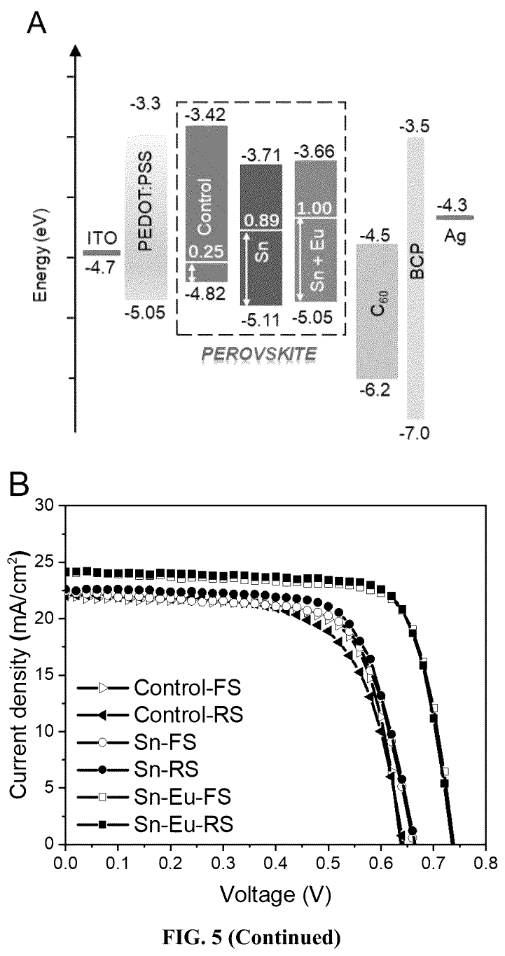

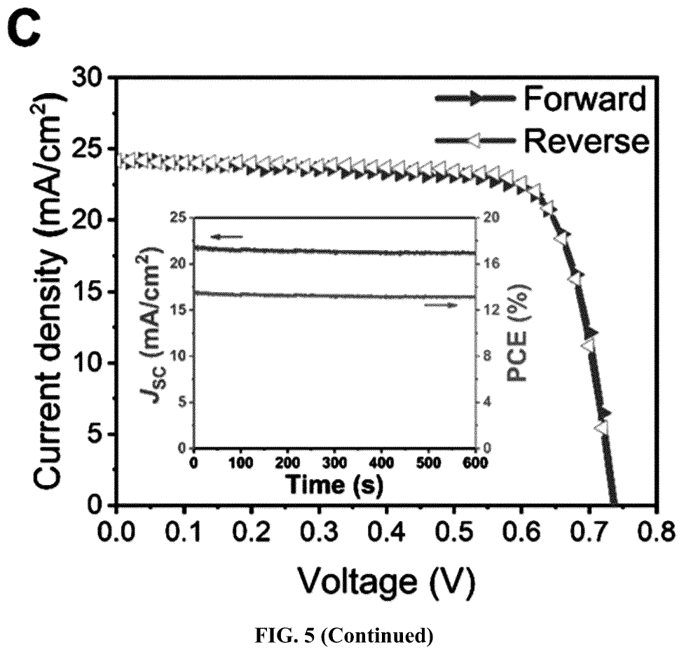

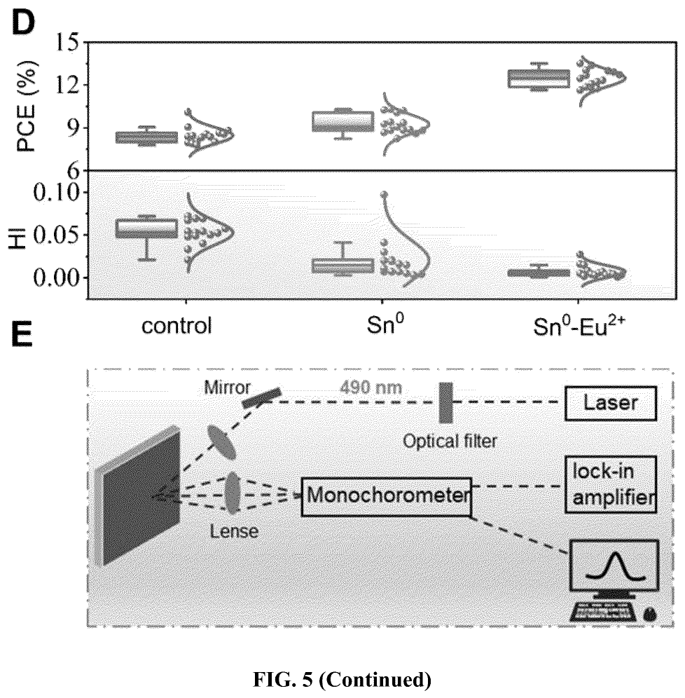

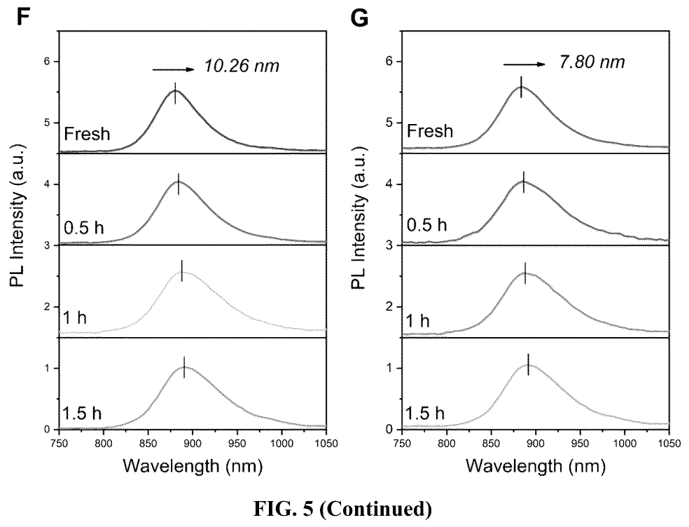

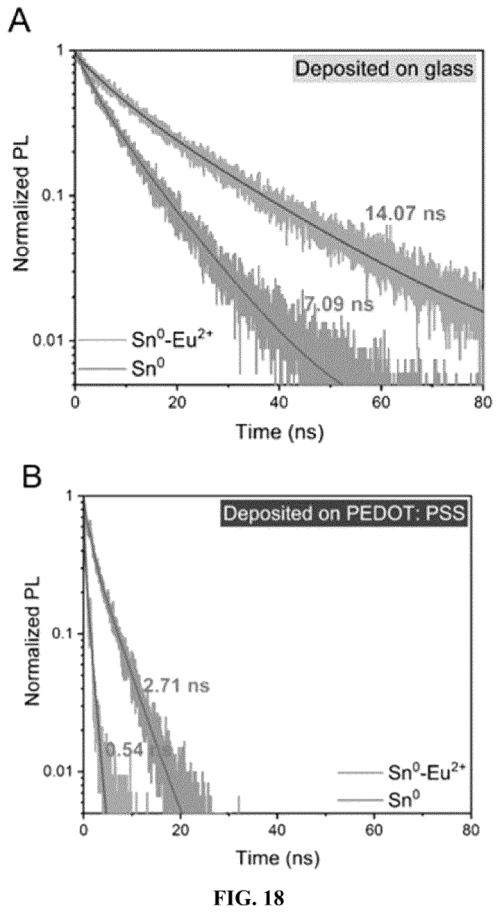

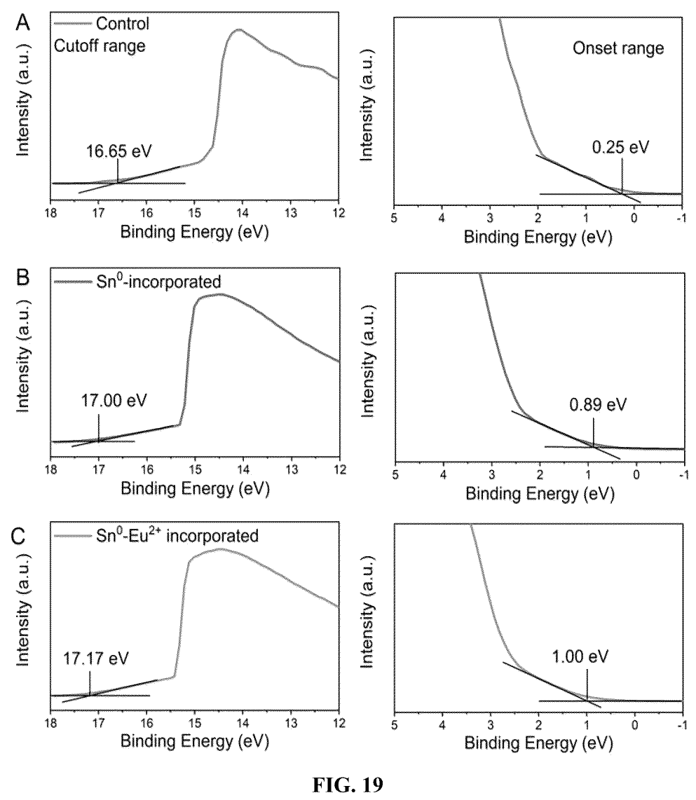

The Sn⁰—Eu²⁺ incorporated film exhibited higher PL intensity compared to those of other samples (FIG. 3H). This may be due to the fact that EuI₂ enhanced the crystallization of perovskites, effectively passivating surface defects. The Sn⁰—Eu²⁺ incorporated film underwent a blue shift to shorter wavelengths, likely due to Sn⁴⁺ removal and reduced lattice structural disorder. Besides, the time-resolved PL (TRPL) spectra showed a prolonged PL lifetime of 14.07 ns for the Sn⁰—Eu²⁺ incorporated film, which is longer than that of Sn⁰-incorporated film (7.09 ns, FIG. 18A). Upon the deposition of an electron transport layer, a significant PL quenching was observed (FIG. 18A and FIG. 28), indicating that the incorporation of Eu²⁺ ions could facilitate charge transfer at the interface. In general, there are various electrostatic potentials for electrons at different positions along the octahedral framework of perovskites. Due to the insulating properties of organic molecules, electron movement is limited to the octahedral framework. In the presence of ammonium ions, the movement of electrons through an iodine framework will alter their electrostatic potential due to steric hindrance. Theoretical calculations in present work demonstrated that the electrostatic potential of the electron in regions a, b, and c varied to different degrees upon EuI₂ doping (FIG. 4A-B). We combined the calculated Fermi levels (E_{F}) of the Sn⁰—Eu²⁺ incorporated sample (E_{F}=−4.3441 eV) with the control (E_{F}=−3.5075 eV) to determine the energy barrier of electron transport. The Sn⁰—Eu²⁺ doping process notably reduced the energy barrier of electrons passing through regions a (−7.31 eV), b (0.51 eV), and c (−5.95 eV) by modifying the spatial arrangement of the Sn—I framework, prolonging carrier lifespan, and facilitating charge collection (FIG. 4C). Furthermore, ultraviolet photoelectron spectroscopy (UPS) spectra (FIG. 19) was used to assess the electronic properties of FASnI₃ perovskite films. Combining with the bandgap calculated from the Tauc plots (FIG. 3G), we constructed an energy-level diagram of the devices (FIG. 5A). In comparison to the control sample (−4.82 eV) and Sn⁰-incorporated sample (−5.11 eV), the valence band minimum (VBM) for Sn⁰—Eu²⁺ incorporated perovskite was −5.05 eV, which is closer to the VBM for PEDOT:PSS (−5.05 eV) and contributes to reducing the energy loss during the charge transfer. It should be noted that the position of the E_{F} for Sn⁰—Eu²⁺ incorporated sample was about 1.00 eV away from VBM, while those of the control and Sn⁰-incorporated devices were about 0.25 and 0.89 eV away from VBM. The upward moving E_{F} indicated that the p-type doping resulted from severe oxidation, could be suppressed after Eu²⁺ doping.

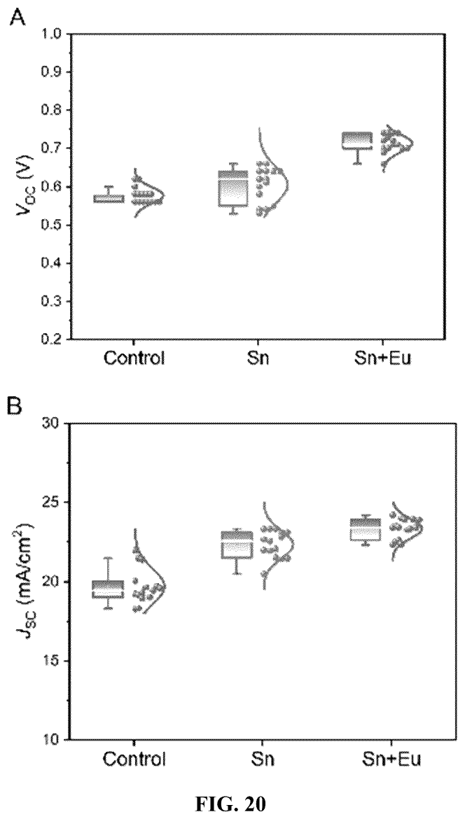

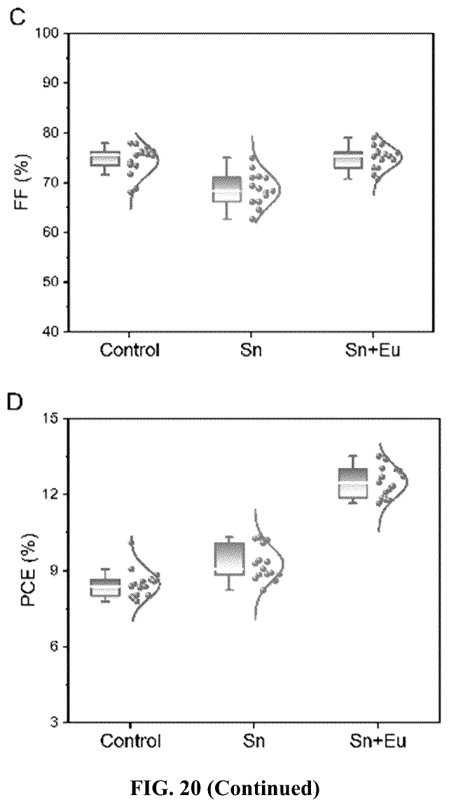

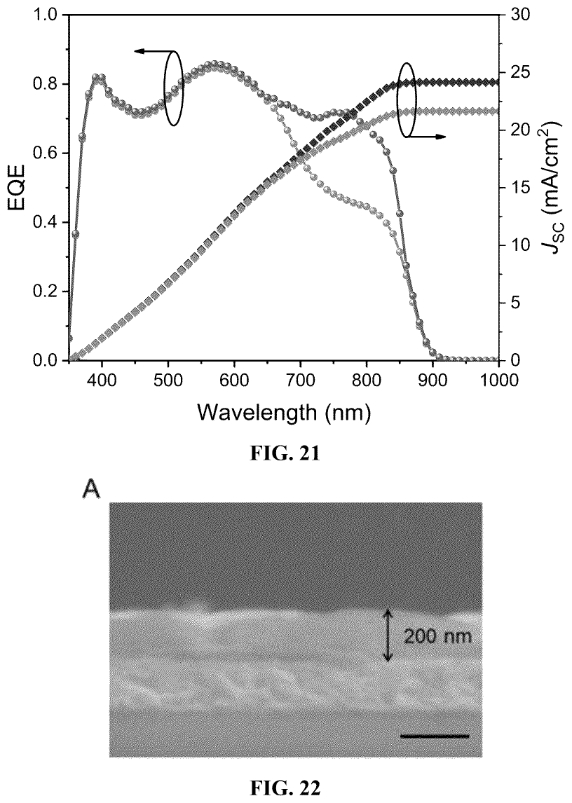

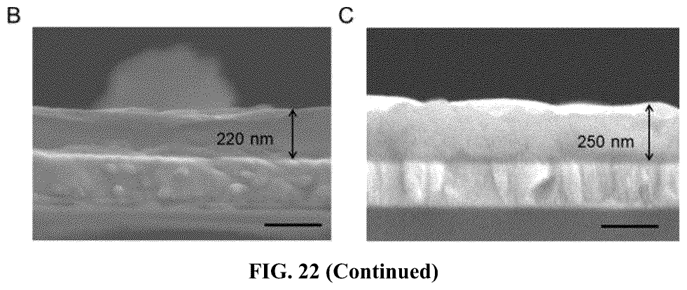

We fabricated inverted planar p-i-n PSCs and measured their current density-voltage (J-V) curves (FIG. 5B). The control device achieved the best PCE of 10.09%, along with a J_{SC} of 21.97 mA/cm², V_{OC} of 0.62 V and FF of 74.10%. After the incorporation of Sn⁰, the PCE increased to 10.69% with the J_{SC} of 22.43 mA/cm², V_{OC} of 0.64 V and FF of 65.98%. In contrast, the Sn⁰—Eu²⁺ incorporated device achieved the highest efficiency of 13.66%, along with a J_{SC} of 24.21 mA/cm², V_{OC} of 0.72 V and FF of 78.34%. The detailed photovoltaic parameters were shown in Table 1. More importantly, there was minimal J-V hysteresis for the Sn⁰—Eu²⁺ incorporated device (FIG. 5C). The maximum PCE output of the Sn⁰—Eu²⁺ incorporated device was measured at a bias of 0.62 V under 100 mW cm⁻² AM 1.5G irradiation, and retained a steady efficiency output of around 13.5% without damping. FIG. 5D and FIG. 20 showed the corresponding box charts for the photovoltaic parameters and hysteresis index (HI). The improvement in PCE was mainly attributed to the faster charge transfer and reduction of defects, leading to increased J_{SC} and V_{OC}. The external quantum efficiency (EQE) measurements for the control and Sn⁰—Eu²⁺ incorporated device yielded integrated J_{SC} values of 21.64 mA cm⁻² and 24.16 mA cm⁻², respectively, which are well matched with the J_{SC} from J-V results. The increased J_{SC} of the Sn⁰—Eu²⁺ incorporated device could be attributed to the higher absorption at the range of 530-840 nm (FIG. 21) and the increased thickness of perovskite film (FIG. 22). The substantial increase in film thickness is intricately linked to the growth of larger crystalline grains within the Sn⁰—Eu²⁺-incorporated film. It should be noted that the Sn⁰—Eu²⁺ incorporated sample displayed less J-V hysteresis compared to the other two samples, potentially resulting from the inhibition of I⁻ migration by Eu²⁺-doping under AM 1.5G illumination. The suppression of hysteresis may be due to multiple factors: 1) Eu²⁺ accumulated at the interstitial sites in the perovskite structure, potentially impeding the I⁻ diffusion; 2) Eu²⁺ can interact with the organic cations to stabilize the perovskite lattice; 3) the distribution of Eu²⁺—Eu³⁺ from surface to the bulk was beneficial to passivate the surface and bulk defects.

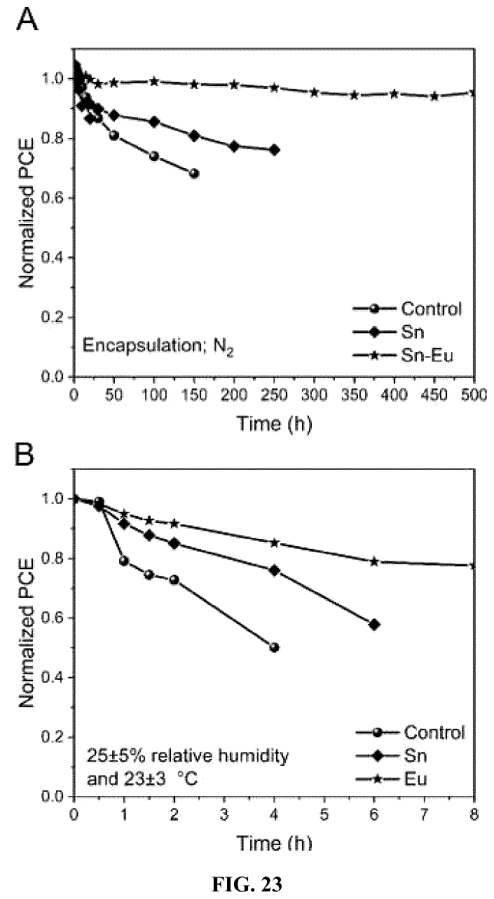

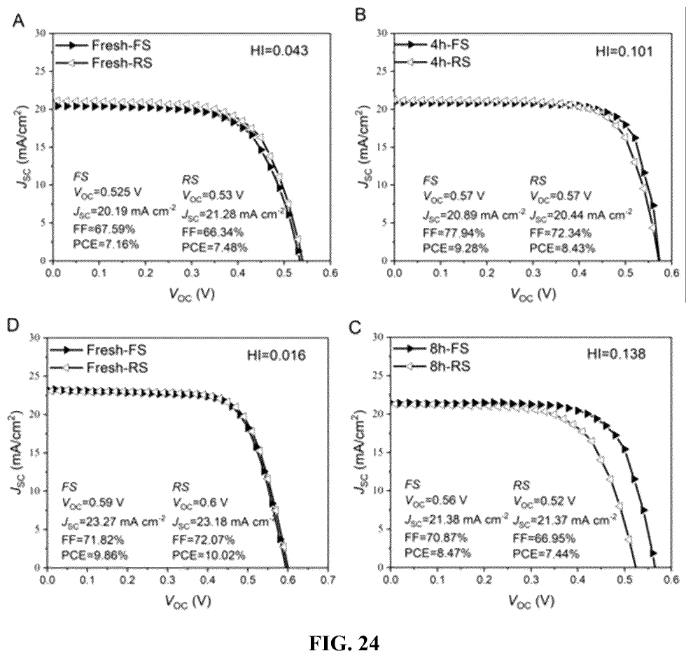

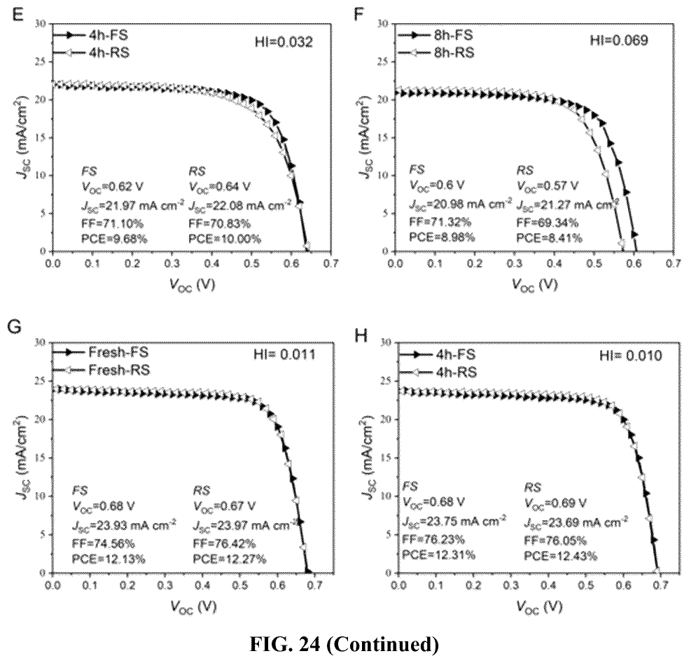

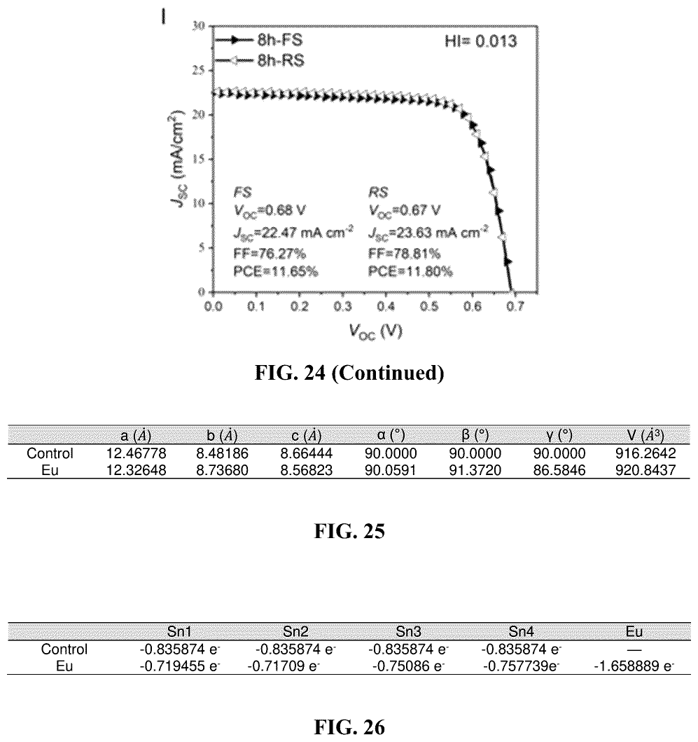

Long-term stability is one of the crucial performance indicators for assessing device performance. The Sn⁰—Eu²⁺ incorporated devices stored in nitrogen atmosphere exhibited favorable stability over 500 h (FIG. 23A). During extended exposure to air and AM 1.5G light soaking (FIG. 23B), the Sn⁰—Eu²⁺ incorporated device demonstrated an impressive 80% retention of its initial efficiency, possibly attributable to its excellent photostability achieved through effective defect suppression and reduced ion migration pathways. To elucidate the impact of ion migration on the photostability of perovskite films, we conducted PL measurements with varying illumination durations (FIG. 5E). Using 490 nm exciting light, we monitored the fluorescence signal and noted a substantial red-shift in the peak of the Sn⁰-incorporated perovskite film, shifting from 880.25 nm to 890.51 nm (10.26 nm difference) as the illumination duration (FIG. 5F). In contrast, the Sn⁰—Eu²⁺ incorporated film exhibited a smaller shift from 883.41 nm to 891.21 nm (7.80 nm offset) (FIG. 5G). We proposed that the reaction between Eu²⁺ and I⁰, coupled with the relief of lattice strain, suppressing the iodide migration and consequently improving the photovoltaic stability of the devices. Since hysteresis is a known consequence of ion migration under illumination, we monitored the J-V curves of the three samples under varying illumination durations (FIG. 24). The hysteresis for devices without EuI₂ was severe (from 4.3% to 13.8% for the control devices and from 1.6% to 6.9% for the Sn⁰-incorporated devices, respectively) due to significant ion migration. The Sn⁰—Eu²⁺ incorporated sample exhibited only a slight variation in HI, from 1.1% to 1.3%, indicating the effective suppression of ion migration by the Eu²⁺ incorporation.

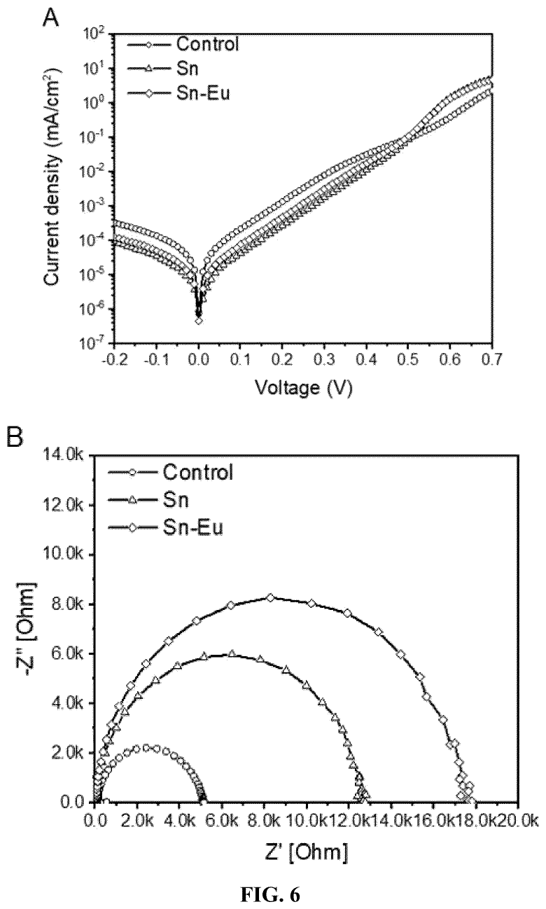

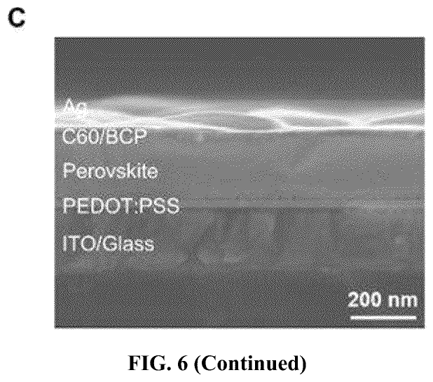

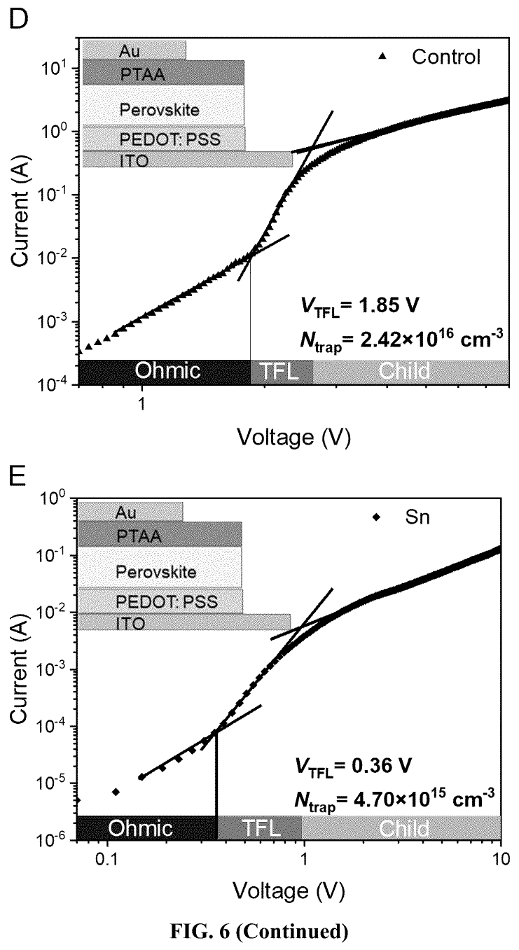

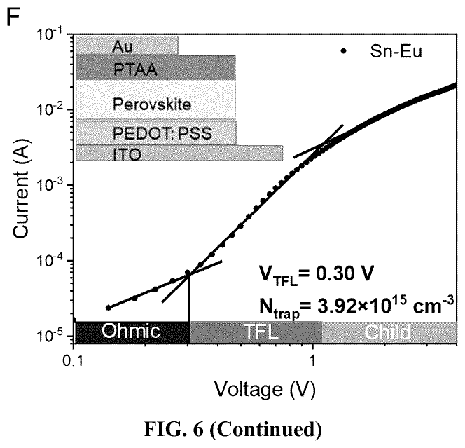

In order to assess the recombination of charge carriers in the devices, we plotted dark current to compare the shunt resistance (FIG. 6A). The Sn⁰—Eu²⁺ incorporated device showed lower dark current (J₀) compared to the other samples, indicating the suppressed charge carrier recombination. Furthermore, we performed electrochemical impedance measurements (EIS) to evaluate their charge transfer (FIG. 6B). The Nyquist plots of these devices exhibited a single semicircle, which is related to the resistance values of charge recombination (R_{rec}). The device with Sn⁰—Eu²⁺ incorporation showed the largest R_{rec}, indicating suppression of Sn—I trap states. To determine the trap density, we conducted space-charge limited current measurements using a device construction of ITO/PEDOT:PSS/Perovskite/PTAA/Au (FIG. 6D-F). The trap-state density (Nₜ) was calculated using the following relation: V_{TFL}=qNₜL²/2εε₀, where ε is the relative dielectric constant, ε₀ is the vacuum permittivity, V_{TFL} is the onset voltage of trap-filled limit region, q is the elementary charge, and L is the thickness of the perovskite films. The cross-section SEM image was shown in FIG. 6C. As shown in FIG. 22, the thickness of the perovskite films under three different conditions is approximately 200, 220, and 250 nm, respectively. The V_{TFL} values of the control, Sn⁰-incorporated and Sn⁰—Eu²⁺ incorporated devices were deduced to be 1.85 V, 0.36 V, and 0.3 V. The corresponding Nₜ are calculated to be 2.42×10¹⁶ cm⁻³, 4.70×10¹⁵ cm⁻³ and 3.92×10¹⁵ cm⁻³, respectively, exhibiting a significant drop of the trap density upon EuI₂ doping.

TABLE 1
Photovoltaic parameters of control, Sn⁰— and Sn⁰—Eu²⁺ incorporated
devices under AM 1.5 G one sun irradiation (100 mW cm⁻²)

| | Scan mode | V_{OC} [V] | J_{SC} [mA cm⁻²] | FF [%] | PCE [%] | HI |
|---|---|---|---|---|---|---|
| Control | FS | 0.62 | 21.97 | 74.10 | 10.09 | 0.068 |
| | RS | 0.64 | 22.08 | 66.83 | 9.45 | |
| Sn⁰ | FS | 0.66 | 22.43 | 69.32 | 10.27 | 0.039 |
| | RS | 0.66 | 22.62 | 71.56 | 10.69 | |
| Sn⁰—Eu²⁺ | FS | 0.72 | 24.20 | 77.54 | 13.51 | 0.011 |
| | RS | 0.72 | 24.21 | 78.34 | 13.66 | |

Note: The PCEs reported in the table are the champion efficiency. FS refers to forward scanning and RS refers to reverse scanning.

### CONCLUSION

Through the experimental and DFT coupled investigations, we have demonstrated that the doping of Eu²⁺ ions into the FASnI₃ perovskite lattice with an optimal amount can relax the lattice strain, modify the film morphology, suppress non-radiative recombination. More importantly, Eu²⁺ doping largely removes the Sn—I defect pairs resulted from the Sn²⁺ oxidation, which is attributed to the thermodynamically favorable redox reactions between Eu²⁺, Sn⁴⁺, and I° in the acidic precursor conditions. As a result, the Eu²⁺-doped Sn PSC device can achieve a high efficiency of 13.66% with increased light and air stabilities. Our work provides a promising approach to mitigate the challenging issues of Sn—I defects for high-performance Sn perovskite photovoltaic devices.

### Experimental

### Materials

All chemicals were employed directly without further treatment after purchase. FAI (99.999%), SnI₂ (99.999%), SnF₂ (99%), EDADI (99.9%), SnCl₂ (99.999%), EuI₂ (99.999%), fullerene-C60 sublimed (99.9%) and bathocuproine (BCP, 99%) were purchased from Sigma Aldrich, Poly(3,4-ethylenedioxythiophene):poly (styrene sulfonate) (PEDOT:PSS, Clevios VP AI 4083) was received from Heraeu. Ultradry dimethyl sulfoxide (DMSO) and ultradry chlorobenzene (CB) were purchased from Sigma Aldrich.

### Device Fabrication

The perovskite precursor solution was prepared by dissolving 336.3 mg SnI₂, 14.1 mg SnF₂, 154.77 mg FAI, 2.75 mg EDADI, 0.1 g/ml Sn powder, 17.64 mg SnCl₂, 4.79 mg EuI₂ in 1 ml DMSO solution and stirring the solution for 2 h at room temperature. ITO glass substrates were cleaned by detergent, DI water, acetone, and isopropanol for 15 min via sonication treatment, respectively. Then, the substrates were treated with ultraviolet-ozone for 20 min before spin-coating PEDOT:PSS. The precursor solution was filtered through 0.25 μm PTFE filter and spin-coated on the PEDOT:PSS layer at 1000 rpm for 10 s, and 5000 rpm for 50 s in the glove box. 150 μL of chlorobenzene was in-situ dripped onto the perovskite film after 40 s during the second step. Afterward, the perovskite films were annealed at 70° C. for 20 min. Finally, 100 nm C₆₀, 15 nm BCP and 200 nm Ag electrode were sequentially evaporated on top of the perovskite under high vacuum.

### Characterization

XRD results were collected on X-ray diffractometer (Rigaku Smart Lab, Japan) with a Cu Ka radiation (the wavelength 1=1.54050 Å). SEM characterizations and XPS spectra were measured by Hitachi Regulus 8100. The NMR was measured on a Bruker AVANCEIII 600 MHZ. The UV-vis absorption measurement was measured at a SHIMADZU UV-vis-NIR spectrometer (UV-1800). Steady-state and time-resolved photoluminescence spectra were measured using Zolix OminiLuo-900 fluorescence spectrophotometer with an excitation wavelength 490 nm. The J-V curves were measured using a Keithley 2450 source meter under irradiation under 100 mW/cm² simulated irradiation from a solar simulator (Saifan 7-IV). EQE measurement was carried out using Zolix OminiLuo-900 fluorescence spectrophotometer. EIS plots were measured on a Zahner electrochemical workstation.

### Computational Methods

All first-principles calculations on bulk systems were performed using DFT in the plane-wave/pseudopotential approach implemented in the Vienna Ab-initio Simulation Package. Exchange-correlation is described the revised Perdew-Burke-Ernzerhof generalized gradient approximation (PBEsol) including dispersion corrections to the total energies via Grimme's DFT-D3 scheme. Within the density functional theory, the first-principle calculations were performed with the Vienna ab initio simulation package (VASP) utilizing the generalized gradient approximation (GGA) in the Perdew-Burke-Ernzerh designed specifically for solids (PBEsol) exchange-correlation functionals. The crystal structures were optimized plane-wave cutoff energy of 600 eV and a Γ-centered 3×4×4 k-point mesh. All geometry structures were fully relaxed until the residual forces on each atom is less than 0.01 eV Å⁻¹. The electronic density of states and difference charge density were calculated using a denser Γ-centered 12×16×16 k-point mesh. Some data post processing in VASP calculations were dealt with the VASPKIT code. Thus, the Sn vacancy formation energy can be obtained by:

$${E}_{v} = {E}_{t o t} ( V ) - {E}_{t o t} ( ideal ) + μ$$

where Eᵥ is the I vacancy formation energy, Eₜₒₜ(V) and Eₜₒₜ(ideal) are the total energy of defective and ideal supercell, respectively, and the μ is the I chemical potential.

What is claimed is:

1. A perovskite comprising Sn²⁺ and Eu²⁺.

2. The perovskite of claim 1 further comprising one or more A⁺ selected from the group consisting of Cs⁺, Rb⁺, CH₃NH₃⁺, CH₃CH₂NH₃⁺, NH₂CH═NH₂⁺, and NH₂C(Me)=NH₂⁺.

3. The perovskite of claim 1 further comprising NH₂CH═NH₂⁺.

4. The perovskite of claim 1, wherein Eu²⁺ and Sn²⁺ are present in the perovskite at a molar ratio of 0.01:99.99 to 5:95, respectively.

5. The perovskite of claim 1, wherein Eu²⁺ and Sn²⁺ are present in the perovskite at a molar ratio of 0.5:99.5 to 2:98, respectively.

6. The perovskite of claim 1 further comprising NH₂CH═NH₂⁺, and Eu²⁺ and Sn²⁺ are present in the perovskite at molar ratio of 0.5:99.5 to 2:98, respectively.

7. The perovskite of claim 1, wherein the perovskite has Formula 1:
(A⁺)(Sn²⁺)(X⁻)₃·m[(Eu²⁺)(Y⁻)₂] 1
wherein m is 0.001-0.05;
X⁻ for each instance is independently F⁻, Cl⁻, Br⁻, or I⁻;
Y⁻ for each instance is independently F⁻, Cl⁻, Br⁻, or I⁻; and
A⁺ is Cs⁺, Rb⁺, CH₃NH₃⁺, CH₃CH₂NH₃⁺, H(C═NH₂)NH₂⁺, Me(C═NH₂)NH₂⁺, or a mixture thereof.

8. The perovskite of claim 7, wherein A⁺ is H(C═NH₂)NH₂⁺.

9. The perovskite of claim 7, wherein m is 0.005-0.02.

10. The perovskite of claim 7, wherein A⁺ is H(C═NH₂)NH₂⁺ and m is about 0.01.

11. The perovskite of claim 10, wherein each of X⁻ and Y⁻ is I.

12. The perovskite of claim 1, wherein the perovskite has Formula 2:
(H(C═NH₂)NH₂⁺)(Sn²⁺)(I⁻)₃·m[(Eu²⁺)(I⁻)₂] 2
wherein m is about 0.010101.

13. A perovskite precursor solution comprising one or more tin salts, EuY₂, AZ, optionally tin powder, and a solvent, wherein the one or more tin salts is represented by the formula SnX₂, A is Cs⁺, Rb⁺, CH₃NH₃⁺, CH₃CH₂NH₃⁺, H(C═NH₂)NH₂⁺, Me(C═NH₂)NH₂⁺, or a mixture thereof, X for each instance is independently F⁻, Cl⁻, Br⁻, I⁻, or a mixture thereof, Y for each instance is independently F⁻, Cl⁻, Br⁻, I⁻, or a mixture thereof, Z is F⁻, Cl⁻, Br⁻, or I⁻, and the solvent comprises dimethyl formamide (DMF), dimethyl sulfoxide (DMSO), or a mixture thereof.

14. The perovskite precursor solution of claim 13, wherein the one or more tin salts comprises SnF₂, SnCl₂, and SnI₂.

15. The perovskite precursor solution of claim 13, wherein AZ is H(C═NH₂)NH₂I.

16. The perovskite precursor solution of claim 13, wherein Y is I⁻.

17. The perovskite precursor solution of claim 13 further comprising ethanediamine dihydroiodide.

18. The perovskite precursor solution of claim 13, wherein the perovskite precursor solution comprises tin powder, SnF₂, SnCl₂, SnI₂, EuI₂, H(C═NH₂)NH₂I, and DMSO.

19. An electronic device comprising:
a substrate layer;
a transparent conductive layer disposed on a surface of the substrate layer,
a hole-transport layer disposed on the surface of the transparent conductive layer;
a perovskite layer comprising the perovskite of claim 1 disposed on a surface of the hole-transport layer;
an electron-transport layer disposed on the surface of the perovskite functional layer; and
a metal electrode disposed on the surface of the electron-transport layer.

20. The electronic device of claim 19, wherein the electronic device has a power conversion efficiency (PCE) of 12-13.66%.

21. The electronic device of claim 19, wherein the perovskite has Formula 2:
(H(C═NH₂)NH₂⁺)(Sn²⁺)(I⁻)₃·m[(Eu²⁺)(I⁻)₂] 2
wherein m is about 0.010101 and the electronic device is more stable than an electronic device comprising a perovskite of Formula 3:
(H(C═NH₂)NH₂⁺)(Sn²⁺)(I⁻)₃ 3.
